(19) United States
(12) Patent Application Publication
(10) Pub. No.: US 2025/0063834 A1
(43) Pub. Date: Feb. 20, 2025

(54) FULL BACKSIDE DEEP TRENCH ISOLATION STRUCTURE FOR A SEMICONDUCTOR PIXEL SENSOR ARRAY

(71) Applicant: Taiwan Semiconductor Manufacturing Company, Ltd., Hsinchu (TW)

(72) Inventors: Chieh-En CHEN, Tainan City (TW); Chen-Hsien LIN, Tainan City (TW); Shyh-Fann TING, Tainan City (TW); Wei-Chih WENG, Tainan City (TW); Feng-Chi HUNG, Tainan City (TW)

(21) Appl. No.: 18/451,691

(22) Filed: Aug. 17, 2023

(51) Int. Cl. H01L 27/146

(52) U.S. Cl. CPC H01L 27/1464; H01L 27/1463; H01L 27/14636; H01L 27/14685

(57) ABSTRACT

A polysilicon well is formed at a cross-road portion between a plurality of pixel sensors in a pixel sensor array. Moreover, the underlying oxide layer between the polysilicon well and a semiconductor layer of the pixel sensor array may be thinner than other areas of the oxide layer. The polysilicon well and the thinner oxide layer may reduce the likelihood of and/or the magnitude of lateral etching that occurs during etching of the semiconductor layer to form recesses in which a BDTI structure of the pixel sensor array is formed. Moreover, the bottom of the BDTI structure being surrounded by the polysilicon well enables a voltage bias to be applied to the BDTI structure through the polysilicon well to passivate damage that might have occurred to the semiconductor layer around the bottom of the BDTI structure.

### BACKGROUND

A complementary metal oxide semiconductor (CMOS) image sensor (CIS) may include a plurality of pixel sensors. A pixel sensor of the CMOS image sensor may include a transfer gate transistor, which may include a photodiode configured to convert photons of incident light into a photocurrent of electrons and a transfer gate configured to control the flow of the photocurrent between the photodiode and a drain region. The drain region may be configured to receive the photocurrent such that the photocurrent can be measured and/or transferred to other areas of the CMOS image sensor.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram of an example of a pixel sensor described herein.

FIGS. 2A and 2B are diagrams of an example implementation 200 of a pixel sensor array 202 described herein.

FIGS. 3A-3D are diagrams of an example implementation of the pixel sensor array described herein.

FIG. 4 is a diagram of an example implementation of the pixel sensor array described herein.

FIGS. 5A-5J are diagrams of an example implementation of forming an example implementation of the pixel sensor array described herein.

FIG. 6 is a diagram of an example implementation of the pixel sensor array described herein.

FIGS. 7A-7G are diagrams of an example implementation of forming an example implementation of the pixel sensor array described herein.

FIG. 8 is a diagram of an example implementation of the pixel sensor array described herein.

FIGS. 9A-9G are diagrams of an example implementation of forming an example implementation of the pixel sensor array described herein.

FIGS. 10A and 10B are diagrams of an example implementation of the pixel sensor array described herein.

FIGS. 11A and 11B are diagrams of an example implementation of the pixel sensor array described herein.

FIGS. 12A and 12B are diagrams of an example implementation of the pixel sensor array described herein.

FIG. 13 is a flowchart of an example process associated with forming a pixel sensor array described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Pixel sensors in a pixel sensor array are often separated by trench isolation structures. For example, a backside deep trench isolation (BDTI) structure may electrically and/or optically isolate pixel sensors in a pixel sensor array. The BDTI structure may include a grid of intersecting trenches arranged around the pixel sensors. Some regions of the BDTI structure (referred to as a non-cross-road portions or non-X-road portions) may border (or may be included between) one or two pixel sensors in the pixel sensor array. Other regions (referred to as a cross-road portions or X-road portions) of the BDTI structure may be located at an intersection between corners of three or more pixel sensors in the pixel sensor array.

An etch rate for etching recesses for the BDTI structure at cross-road portions generally may be greater relative to an etch rate for etching recesses at non-cross-road portions of the BDTI structures due to increased critical dimensions (CDs) between the photodiode regions. The increase in CDs results from greater diagonal spacing between photodiode regions at the cross-road portions relative to lateral spacing between photodiode regions at the non-cross-road portions. The increased CDs result in increased trench depth loading. In some cases, a plasma etch may be performed to etch the recesses, in which ions in a plasma are used to bombard the recesses to remove material to perform the etch. Radicals in the plasma may more easily diffuse into the sidewalls and bottom surface of the recesses due to the increased CDs at the cross-road portions, thereby resulting in lateral etching when etching through a semiconductor layer and/or through an underlying oxide layer.

The lateral etching may result in damage to the crystalline structure of photodiode regions of the pixel sensors, thereby increasing the dark current in the photodiode regions. Dark current is an electrical current that may occur in a photodiode region from sources other than incident light, such as damage to the crystalline structure of the photodiode region. Dark current may cause increased noise and other defects in images and/or video captured based on the photocurrent generated by the photodiode region. For example, dark current may artificially increase the photocurrent generated by the photodiode region, which may decrease the low-light performance and/or may cause some of the pixels in an image or a video to register as a white pixel or a hot pixel.

In some implementations described herein, a polysilicon well is formed at a cross-road portion between a plurality of pixel sensors in a pixel sensor array. Moreover, the portions of the underlying oxide layer between the polysilicon well and a semiconductor layer of the pixel sensor array may be thinner than other portions of the oxide layer. The polysilicon well and the thinner oxide layer may reduce the likelihood of and/or the magnitude of lateral etching that occurs during etching of the semiconductor layer to form recesses in which a BDTI structure of the pixel sensor array is formed. Moreover, the semiconductor property of the polysilicon well enables a voltage bias to be applied to the BDTI structure through the polysilicon well.

The reduced likelihood of and/or the reduced magnitude of lateral etching in the cross-road portion may result in reduced dark current in the photodiode regions relative to another pixel sensor array that does not include the polysilicon well. Moreover, applying the voltage bias to the BDTI structure through the polysilicon well may enable damage that might occur to the photodiode regions to be passivated by increasing hole density in the semiconductor layer surrounding the BDTI structures (e.g., relative to no voltage bias being applied), thereby further reducing the dark current in the pixel sensor array. In addition, the polysilicon well may provide an increased process window for etching recesses for the BDTI structure, which may reduce the process complexity for forming the BDTI structures.

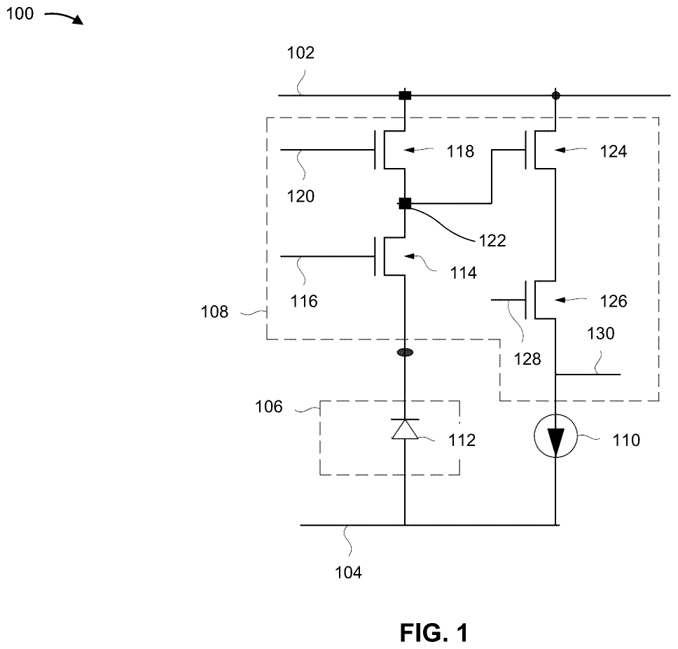

FIG. 1 is a diagram of an example of a pixel sensor 100 described herein. The pixel sensor 100 may include a front side pixel sensor (e.g., a pixel sensor that is configured to receive photons of light from a front side of a sensor die), a back side pixel sensor (e.g., a pixel sensor that is configured to receive photons of light from a back side of a sensor die), and/or another type of pixel sensor. The pixel sensor 100 may be electrically connected to a supply voltage (V_{dd}) 102 and an electrical ground 104.

The pixel sensor 100 includes a sensing region 106 that may be configured to sense and/or accumulate incident light (e.g., light directed toward the pixel sensor 100). The pixel sensor 100 also includes a control circuitry region 108. The control circuitry region 108 is electrically connected with the sensing region 106 and is configured to receive a photocurrent 110 that is generated by the sensing region 106. Moreover, the control circuitry region 108 is configured to transfer the photocurrent 110 from the sensing region 106 to downstream circuits such as amplifiers or analog-to-digital (AD) converters, among other examples.

The sensing region 106 includes a photodiode 112. The photodiode 112 may absorb and accumulate photons of the incident light, and may generate the photocurrent 110 based on absorbed photons. The magnitude of the photocurrent 110 is based on the amount of light collected in the photodiode 112. Thus, the accumulation of photons in the photodiode 112 generates a build-up of electrical charge that represents the intensity or brightness of the incident light (e.g., a greater amount of charge may correspond to a greater intensity or brightness, and a lower amount of charge may correspond to a lower intensity or brightness).

The photodiode 112 is electrically connected with a source of a transfer gate 114 in the control circuitry region 108. The transfer gate 114 is configured to control the transfer of the photocurrent 110 from the photodiode 112. The photocurrent 110 is provided from the source of the transfer gate 114 to a drain of the transfer gate 114 based on selectively switching a gate of the transfer gate 114. The gate of the transfer gate 114 may be selectively switched by applying a transfer voltage (Vₜₓ) 116 to the transfer gate 114. In some implementations, the transfer voltage 116 being applied to the transfer gate 114 causes a conductive channel to form between the source and the drain of the transfer gate 114, which enables the photocurrent 110 to traverse along the conductive channel from the source to the drain. In some implementations, the transfer voltage 116 being removed from the transfer gate 114 (or the absence of the transfer voltage 116) causes the conductive channel to be removed such that the photocurrent 110 cannot pass from the source to the drain.

The control circuitry region 108 further includes a reset gate 118. The reset gate 118 is electrically connected to the supply voltage 102. The reset gate 118 may be controlled by a reset voltage (Vrst) 120. The transfer gate 114 and the reset gate 118 may be electrically coupled with a floating diffusion node 122. The reset voltage 120 may be applied to the reset gate 118 to pull the drain of the transfer gate 114 to a high voltage (e.g., to the supply voltage 102) to “reset” the floating diffusion node 122 (e.g., by draining any residual charge in the floating diffusion node 122) prior to activation of the transfer gate 114 to transfer the photocurrent 110 from the photodiode 112 to the floating diffusion node 122.

The photocurrent 110 may be used to apply a floating diffusion voltage (V_{fd}) to a source follower gate 124 of the control circuitry region 108. This permits the photocurrent 110 to be observed without removing or discharging the photocurrent 110 from the floating diffusion node 122. The reset gate 118 may instead be used to remove or discharge the photocurrent 110 from the floating diffusion node 122.

The source follower gate 124 functions as a high impedance amplifier for the pixel sensor 100. The source follower gate 124 provides a voltage to current conversion of the floating diffusion voltage. The output of the source follower gate 124 is electrically connected with a row select gate 126, which is configured to control the flow of the photocurrent 110 to external circuitry. The row select gate 126 is controlled by selectively applying a select voltage (V_{di}) 128 to the gate of the row select gate 126. This permits the photocurrent 110 to flow to an output 130 of the pixel sensor 100.

As indicated above, FIG. 1 is provided as an example. Other examples may differ from what is described with regard to FIG. 1.

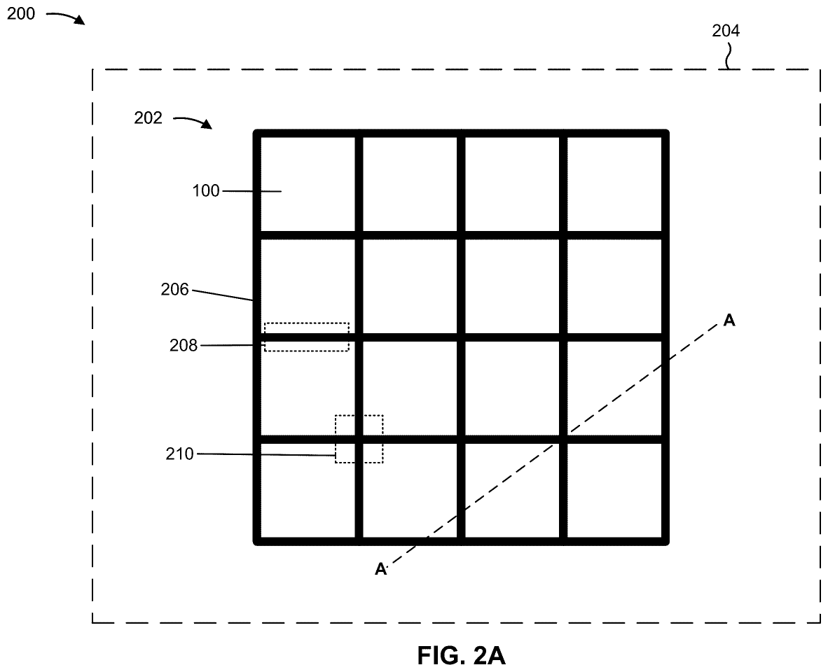

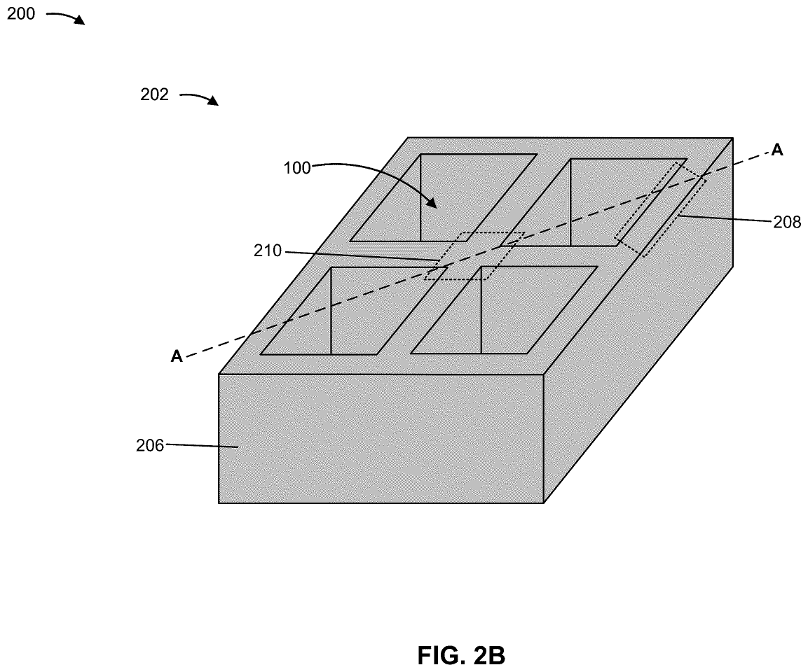

FIGS. 2A and 2B are diagrams of an example implementation 200 of a pixel sensor array 202 described herein. FIG. 2A illustrates a top-down view of the pixel sensor array 202 and FIG. 2B illustrates a perspective view of the pixel sensor array 202. In some implementations, the pixel sensor array 202 may be included in an image sensor 204. The image sensor 204 may include a CMOS image sensor (CIS), a backside illuminated (BSI) CMOS image sensor, a front side illuminated (FSI) CMOS image sensor, or another type of image sensor.

As shown in FIG. 2A, the pixel sensor array 202 may include a plurality of pixel sensors 100. As further shown in FIG. 2A, the pixel sensors 100 may be arranged in a grid. In some implementations, the pixel sensors 100 are square-shaped (as shown in the example in FIG. 2A). In some implementations, the pixel sensors 100 include other shapes such as rectangle shapes, circle shapes, octagon shapes, diamond shapes, and/or other shapes.

The pixel sensors 100 may be configured to sense and/or accumulate incident light (e.g., light directed toward the pixel sensor array 202). For example, a pixel sensor 100 may absorb and accumulate photons of the incident light in a photodiode. The accumulation of photons in the photodiode may generate a charge representing the intensity or brightness of the incident light (e.g., a greater amount of charge may correspond to a greater intensity or brightness, and a lower amount of charge may correspond to a lower intensity or brightness). In some implementations, at least a subset of the pixel sensors 100 may be configured to sense incident light in the visible light wavelength spectrum. In some implementations, at least a subset of the pixel sensors 100 may be configured to sense incident light in the infrared light or near infrared light wavelength spectrum.

In some implementations, the size of the pixel sensors 100 (e.g., the width or the diameter) of the pixel sensors 100 is in a range from approximately 0.5 micron to approximately 2 microns. In some implementations, the size of the pixel sensors 100 (e.g., the width or the diameter) of the pixel sensors 100 is less than approximately 1 micron. In these examples, the pixel sensors 100 may be referred to as sub-micron pixel sensors. Sub-micron pixel sensors may decrease the pixel sensor pitch (e.g., the distance between adjacent pixel sensors) in the pixel sensor array 202, which may enable increased pixel sensor density in the pixel sensor array 202 (which can increase the performance of the pixel sensor array 202).

The pixel sensors 100 may be electrically and optically isolated by a BDTI structure 206 included in the pixel sensor array 202. The BDTI structure 206 may include a plurality of interconnected and intersecting trenches that are filled with one or more types of materials, such as a dielectric material (e.g., a oxide-containing material, a high dielectric constant (high-k) dielectric material), a polysilicon material, and/or another type of material. The trenches of the BDTI structure 206 may be included around the perimeters of the pixel sensors 100 such that the BDTI structure 206 surrounds the pixel sensors 100 (and the photodiodes and drain regions included therein), as shown in FIG. 2A.

As shown in FIG. 2B, the portions of the BDTI structure 206 between one or two pixel sensors 100 may be referred to as non-cross-road portions 208 of the BDTI structure 206. Portions of the BDTI structure 206 that intersect at corners of three or more pixel sensors 100 may be referred to as cross-road portions 210 of the BDTI structure 206.

The BDTI structure 206 may extend into (and may be included in) a substrate in which the pixel sensors 100 are formed to surround the photodiodes and other structures of the pixel sensors 100 in the substrate. As indicated above, the pixel sensor array 202 may be included in a BSI CMOS image sensor. In these examples, the BDTI structure 206 may be formed from the backside of substrate of the pixel sensor array 202.

FIGS. 2A and 2B further illustrate a reference cross-section A-A that is used in one or more figures described herein. Cross-section A-A is in a plane across a plurality of pixel sensors 100 of the pixel sensor array 202. The plane extends across one or more non-cross-road portions 208 and one or more cross-road portions 210 of the BDTI structure 206. Subsequent figures refer to this reference cross-section for clarity. In some figures, some reference numbers of components or features illustrated therein may be omitted to avoid obscuring other components or features for ease of depicting the figures.

As indicated above, FIGS. 2A and 2B are provided as an example. Other examples may differ from what is described with regard to FIGS. 2A and 2B.

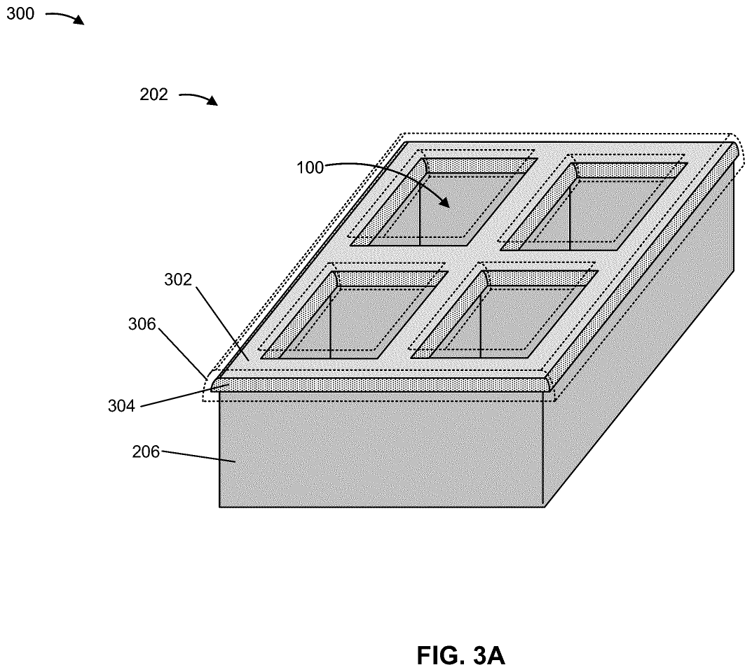

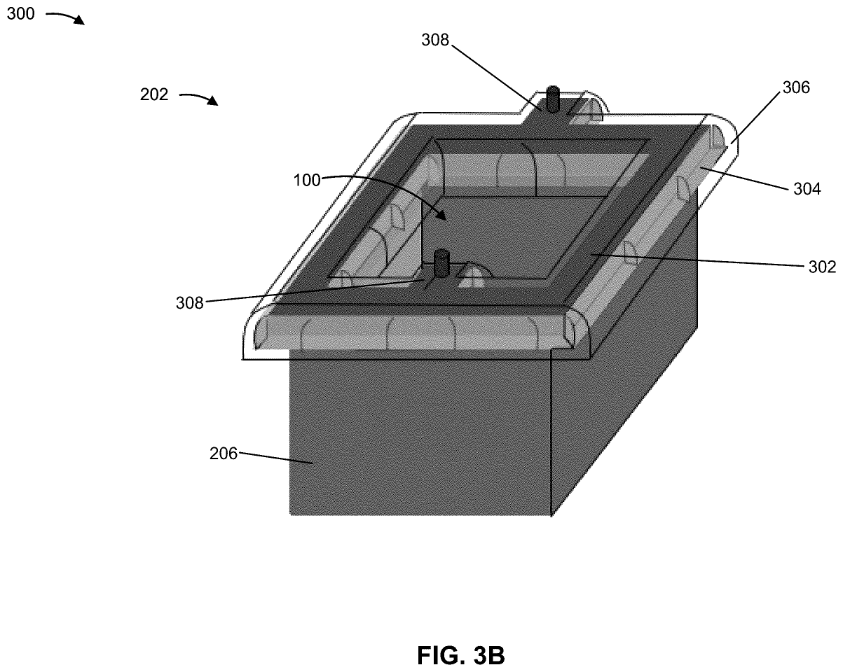

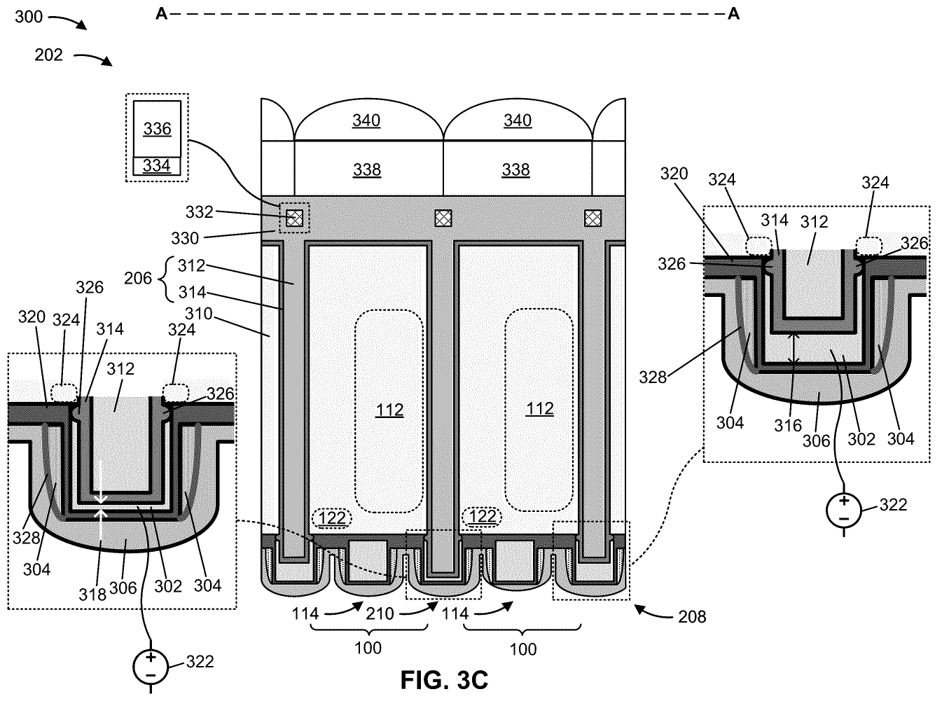

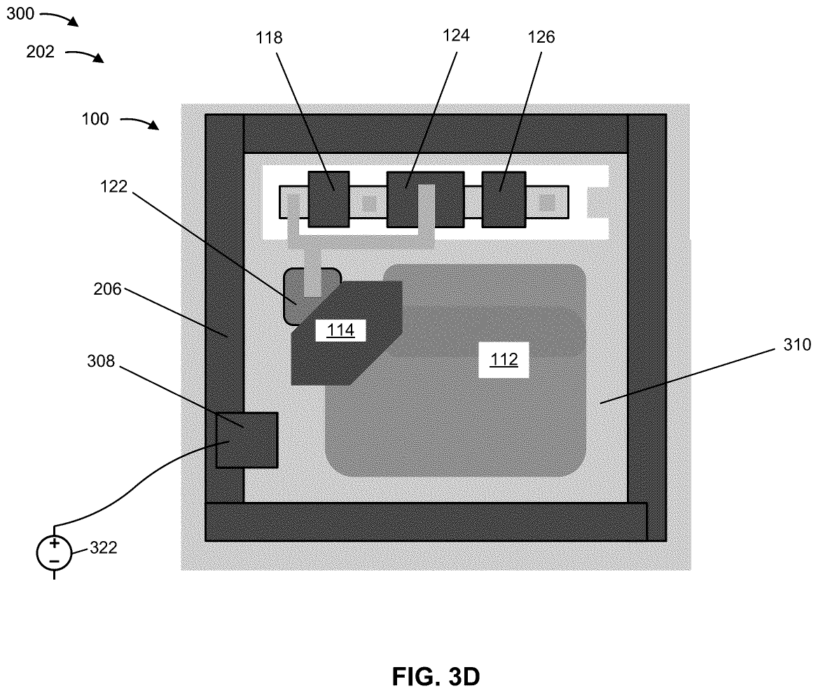

FIGS. 3A-3D are diagrams of an example implementation 300 of the pixel sensor array 202 described herein. As shown in the perspective view in FIG. 3A, the pixel sensor array 202 includes a polysilicon well 302 that conforms to the grid shape of the BDTI structure 206. The polysilicon well 302 may be included to reduce or minimize etching damage in the pixel sensor array 202 that might result during formation of the BDTI structure 206. Additionally and/or alternatively, the polysilicon well 302 enables a voltage bias to be applied around the BDTI structure 206 to increase hole density around the BDTI structure 206 to electrically passivate the etching damage in the pixel sensor array 202 that might result during formation of the BDTI structure 206.

As further shown in FIG. 3A, dielectric sidewall spacers 304 may be included on and/or around sidewalls of the polysilicon well 302. The dielectric sidewall spacers 304 may include one or more dielectric materials such as a silicon oxide (SiOₓ) (e.g., silicon dioxide (SiO₂)), a silicon nitride (SiₓN_{y}), a silicon carbide (SiCₓ), a hafnium oxide (HfOₓ), a silicon oxynitride (SiON), tetraethyl orthosilicate oxide, phosphosilicate glass (PSG), borophosphosilicate glass (BPSG), fluorinated silica glass (FSG), carbon doped silicon oxide, and/or another dielectric material.

As further shown in FIG. 3A, a contact etch stop layer (CESL) 306 may be included over the polysilicon well 302 and over the dielectric sidewall spacers 304. The CESL 306 is illustrated in transparency in FIG. 3A for purposes of clarity. The CESL 306 may include one or more dielectric materials such as a silicon oxide (SiOₓ) (e.g., silicon dioxide (SiO₂)), a silicon nitride (SiₓN_{y}), a silicon carbide (SiCₓ), a hafnium oxide (HfOₓ), a silicon oxynitride (SiON), tetraethyl orthosilicate oxide, phosphosilicate glass (PSG), borophosphosilicate glass (BPSG), fluorinated silica glass (FSG), carbon doped silicon oxide, and/or another dielectric material.

As further shown in FIG. 3A, in the example implementation 300 of the pixel sensor array 202, the polysilicon well 302, the dielectric sidewall spacers 304, and the CESL 306 may be included in the non-cross-road portions 208 and in the cross-road portions 210 of the BDTI structure 206. The polysilicon well 302, the dielectric sidewall spacers 304, and the CESL 306 may be formed over a front side of a substrate of the pixel sensor array 202.

As shown in another perspective view of the pixel sensor array 202 in FIG. 3B, electrodes 308 may extend from and may be coupled with the polysilicon well 302. The electrodes 308 enable voltage bias to be applied to the polysilicon well 302 to increase hole density around the BDTI structure 206 to electrically passivate the etching damage in the pixel sensor array 202 that might result during formation of the BDTI structure 206. The voltage bias may be provided by a voltage source through a back end of line (BEOL) region of an image sensor in which the pixel sensor array 202 is included.

FIG. 3C illustrates a cross-section view of the example implementation 300 of the pixel sensor array 202. The cross-section view in FIG. 3C is along the cross-section A-A of the pixel sensor array 202 in FIGS. 2A and 2B. As shown in FIG. 3C, the pixel sensors 100 of the pixel sensor array 202 may be formed in and/or on a semiconductor layer 310, which may be the substrate of the pixel sensor array 202. The semiconductor layer 310 may include a silicon (Si) substrate, a substrate formed of a material including silicon, a III-V compound semiconductor material substrate such as gallium arsenide (GaAs), a germanium (Ge) substrate, a silicon germanium (SiGe) substrate, or another type of semiconductor substrate.

The pixel sensors 100 may include a photodiode 112 and a floating diffusion node 122 in the semiconductor layer 310 between the BDTI structure 206. The photodiode 112 may include a plurality of regions of the semiconductor layer 310 that are doped with various types of ions to form a p-n junction or a PIN junction (e.g., a junction between a p-type portion, an intrinsic (or undoped) type portion, and an n-type portion). For example, the semiconductor layer 310 may be doped with an n-type dopant to form one or more n-type regions of the photodiode 112, and the semiconductor layer 310 may be doped with a p-type dopant to form a p-type region of the photodiode 112. The photodiode 112 may be configured to absorb photons of incident light (e.g., visible light, near infrared light). The absorption of photons causes the photodiode 112 to accumulate a charge (referred to as a photocurrent 110) due to the photoelectric effect. Photons may bombard the photodiode 112, which causes emission of electrons and holes in the photodiode 112, which causes the photocurrent 110 to be generated.

The floating diffusion node 122 may include a highly-doped n-type region (e.g., an n⁺ doped region) of the semiconductor layer 310. In some implementations, a drain extension region is included in the semiconductor layer 310 adjacent to the floating diffusion node 122. The drain extension region may include lightly-doped n-type region(s) that facilitate the transfer of photocurrent 110 from the photodiode 112 to the floating diffusion node 122.

A pixel sensor 100 may include a transfer gate 114 on a front side of the semiconductor layer 310. The transfer gate 114 may be configured to selectively control the transfer of a photocurrent from a photodiode 112 of the pixel sensor 100 to the floating diffusion node 122 of the pixel sensor 100 by selectively controlling the conductivity of the semiconductor layer 310 between the photodiode 112 and the floating diffusion node 122.

As further shown in FIG. 3C, the BDTI structure 206 may extend through the semiconductor layer 310. In particular, the BDTI structure 206 may extend fully through (may be included fully through) the semiconductor layer 310 between a front side of the semiconductor layer 310 and a backside of the semiconductor layer 310. Accordingly, the BDTI structure 206 may be referred to as a full BDTI (F-BDTI) structure 206. The BDTI structure 206 may be formed from the backside of the semiconductor layer 310 as part of backside processing of the pixel sensor array 202. The backside of the semiconductor layer 310 may be the side of the semiconductor layer 310 opposing the front side on which the transfer gates 114 are included.

The BDTI structure 206 may include elongated structures of dielectric material 312 and a dielectric liner 314 between the dielectric material 312 and the semiconductor layer 310. The dielectric liner 314 may be included on sidewalls and on a bottom surface of the BDTI structure 206, and may be included as an antireflective coating (ARC) and/or to further facilitate electrical and/or optical isolation of the pixel sensors 100. In some implementations, the dielectric material 312 includes a silicon oxide (SiOₓ) (e.g., silicon dioxide (SiO₂)), a silicon nitride (SiₓN_{y}), a silicon carbide (SiCₓ), a hafnium oxide (HfOₓ), a silicon oxynitride (SiON), tetraethyl orthosilicate oxide, phosphosilicate glass (PSG), borophosphosilicate glass (BPSG), fluorinated silica glass (FSG), carbon doped silicon oxide, and/or another dielectric material. In some implementations, the dielectric liner 314 may include a high-k dielectric material such as a silicon nitride (SiₓN_{y}), a hafnium oxide (HfOₓ), and/or another high-k dielectric material.

As further shown in FIG. 3C, the BDTI structure 206 may extend or stick out past the front side of the semiconductor layer 310 and into the polysilicon well 302. The polysilicon well 302 provides buffer areas for over-etching when forming recesses in which the BDTI structure 206 is formed. The polysilicon well 302, alone or in combination with the CESL 306, may increase the process window for over-etching in that the polysilicon well 302, alone or in combination with the CESL 306, may accommodate a greater amount of over-etching than just the CESL 306 alone, which increases the likelihood that the recesses, in which the BDTI structure 206 is formed, are formed fully through the semiconductor layer 310.

As shown in close-up views of a non-cross-road portion 208 of the BDTI structure 206 and a cross-road portion 210 of the BDTI structure 206, the amount or depth of etching of the recesses for the BDTI structure 206 may be greater in the cross-road portion 210 than in the non-cross-road portion 208. As described above, this may be due to the increased etch loading in the cross-road portion 210 relative to the non-cross-road portion 208. Accordingly, a distance 316 between a bottom of the BDTI structure 206 in the non-cross-road portion 208 may be greater than a distance 318 between a bottom of the BDTI structure 206 in the cross-road portion 210.

The polysilicon well 302 may be formed to a thickness of approximately 800 angstroms to approximately 1200 angstroms to accommodate the amount of over-etching in both the non-cross-road portion 208 and the cross-road portion 210. Moreover, self-aligned implant tunning and device failures may occur in the pixel sensor array 202 if the thickness of the polysilicon well 302 is less than approximately 800 angstroms, whereas degraded topography might result in processing defects if the thickness of the polysilicon well 302 is greater than approximately 1200 angstroms. However, other values for the thickness of the polysilicon well 302, and ranges other than approximately 800 angstroms to approximately 1200 angstroms, are within the scope of the present disclosure.

As further shown in FIG. 3C, the dielectric sidewall spacers 304 may be included on sidewalls of the polysilicon well 302. The CESL may be included over the dielectric sidewall spacers 304 and over (or under) the top surface (or bottom surface) of the polysilicon well 302. In some implementations, a thickness of the CESL 306 under the polysilicon well 302 is included in a range of approximately 300 angstroms to approximately 500 angstroms. If the thickness of the CESL 306 is less than approximately 300 angstroms, the CESL 306 may provide an insufficient etch stop barrier for forming contacts to the floating diffusion nodes 122, whereas the CESL 306 may provide a sufficient etch stop barrier for forming contacts to the floating diffusion nodes 122 if the thickness of the CESL 306 is at least approximately 300 angstroms. If the thickness of the CESL 306 is greater than approximately 500 angstroms, under-etching of the CESL 306 may occur when forming contacts to the floating diffusion nodes 122, whereas the likelihood of under-etching is reduced if the thickness of the CESL 306 is approximately 500 angstroms or less. However, other values for the thickness of the CESL 306, and ranges other than approximately 300 angstroms to approximately 500 angstroms, are within the scope of the present disclosure.

As further shown in FIG. 3C, additional dielectric layers may be included over the front side of the semiconductor layer 310 in the non-cross-road portion 208 and the cross-road portion 210. For example, an oxide layer 320 may be included between the semiconductor layer 310 and the CESL 306. Moreover, the oxide layer 320 may be included between the semiconductor layer 310 and the polysilicon well 302. In some implementations, the oxide layer 320 may be included between the polysilicon well 302 and the dielectric sidewall spacers 304 and/or between the bottom of the polysilicon well 302 and the CESL 306. The oxide layer 320 may include an oxide-containing material, such as a hafnium oxide (HfOₓ), a silicon oxynitride (SiON), and/or another oxide-containing dielectric material.

The thickness of portions of the oxide layer 320 between the semiconductor layer 310 and the polysilicon well 302 may be less than the thickness of other portions of the oxide layer 320. The oxide layer 320 may be thinner between the semiconductor layer 310 and the polysilicon well 302 to reduce lateral etching (and the associated damage to the semiconductor layer 310) in the oxide layer 320 when over-etching occurs when forming the recesses for the BDTI structure 206. The polysilicon well 302 may further reduce lateral etching (and the associated damage to the semiconductor layer 310) in that the polysilicon well 302 may facilitate faster over-etching of the recesses due to the reduced etch selectivity between the polysilicon well 302 and the semiconductor layer 310 relative to the etch selectivity between the semiconductor layer 310 and the oxide layer 320. In particular, if the oxide layer 320 were thicker in areas in which the recesses for the BDTI structure 206 are etched, the lesser etch rate of the oxide layer 320 may result in a greater amount of lateral etching in the oxide layer 320. The polysilicon well 302 may facilitate a reduction in thickness of the oxide layer 320 in areas in which the recesses for the BDTI structure 206 are etched while still providing a sufficient over-etch buffer without the need for additional mask layers, thereby reducing the amount of lateral etching in the oxide layer 320. Thus, the polysilicon well 302 and the reduced thickness of the oxide layer 320 between the polysilicon well 302 and the semiconductor layer 310 may enable a low dark current to be achieved for the pixel sensors 100 of the pixel sensor array 202.

To further facilitate a low dark current to be achieved for the pixel sensors 100 of the pixel sensor array 202, a voltage bias 322 may be applied to the polysilicon well 302 (e.g., through the electrodes 308). The voltage bias 322 may result in the formation of regions 324 around the bottoms of the BDTI structure 206 of increased hole density in the semiconductor layer 310, which may passivate damage that occurred in the semiconductor layer 310 due to lateral etch regions 326 in the BDTI structure 206.

In some implementations, another oxide layer 328 (e.g., a remote plasma oxide (RPO) layer) may be included between the dielectric sidewall spacers 304 and the CESL 306, and/or between the oxide layer 320 and the CESL 306.

As further shown in FIG. 3C, a buffer layer 330 may be included over the backside of the semiconductor layer 310. The buffer layer 330 may include a silicon oxide (SiOₓ) (e.g., silicon dioxide (SiO₂)), a silicon nitride (SiₓN_{y}), a silicon carbide (SiCₓ), a hafnium oxide (HfOₓ), a silicon oxynitride (SiON), tetraethyl orthosilicate oxide, phosphosilicate glass (PSG), borophosphosilicate glass (BPSG), fluorinated silica glass (FSG), carbon doped silicon oxide, and/or another dielectric material.

A metal grid 332 may be embedded in the buffer layer 330. The metal grid 332 may be configured to constrain the light in a pixel, resulting in optical crosstalk reduction between pixel sensors 100. The metal grid 332 may substantially conform to the grid shape of the BDTI structure 206 and may include an adhesion layer 334 and a metal layer 336. The adhesion layer 334 may include a titanium nitride (TiN) and/or another suitable material. The metal layer 336 may include tungsten (W) and/or another suitable metal material.

Color filters 338 may be included above and/or on the buffer layer 330. In some implementations, the color filters 338 include visible light color filters configured to filter a particular wavelength or a particular wavelength range of visible light (e.g., red light, blue light, or green light). In some implementations, at least a subset of the color filters 338 includes a near infrared (NIR) filter (e.g., an NIR bandpass filter) configured to permit wavelengths associated with NIR light to pass through the color filters 338 and to block other wavelengths of light. In some implementations, at least a subset of the color filters 338 includes an NIR cut filter configured to block NIR light from passing through the color filters 338. In some implementations, color filters 338 may be omitted from one or more pixel sensors 100 to permit all wavelengths of light to pass through to the associated photodiodes 112. In these examples, the pixel sensor(s) 100 may be configured as a white pixel sensor(s).

Micro-lenses 340 may be included above and/or on the color filters 338. The micro-lenses 340 may include micro-lenses for the pixel sensors 100 configured to focus incident light toward the photodiodes 112 and/or to reduce optical crosstalk between the pixel sensors 100.

FIG. 3D illustrates a top-down view of a pixel sensor 100 included in the pixel sensor array 202. As shown in FIG. 3D, the BDTI structure 206 may be included around the perimeter of the pixel sensor 100. An electrode 308 may be coupled with the BDTI structure 206 to permit a voltage bias 322 to be applied to the BDTI structure 206. A photodiode 112 and a floating diffusion node 122 may be included in the semiconductor layer 310 within the perimeter of the BDTI structure 206. The transfer gate 114 may be included between the photodiode 112 and the floating diffusion node 122. The floating diffusion node 122 may be electrically coupled with a reset gate 118 and a source follower gate 124. The source follower gate 124 may be electrically coupled with a row select gate 126.

In this way, the pixel sensor array 202 includes a plurality of pixel sensors 100 and a BDTI structure 206 surrounding the plurality of pixel sensors 100. The BDTI structure 206 fully extends through the semiconductor layer 310 of the pixel sensor array 202 between a front side of the semiconductor layer 310 and a backside of the semiconductor layer 310. A portion of the BDTI structure 206 extends into and/or is surrounded by a polysilicon well 302 under the semiconductor layer 310. In some implementations, the portion of the BDTI structure 206 may be a non-cross-road portion 208 of the BDTI structure 206 between two pixel sensors 100 of the plurality of pixel sensors 100, and a cross-road portion 210 of the BDTI structure 206, at a corner of at least three pixel sensors 100 of the plurality of pixel sensors 100, may extend into the polysilicon well 302 under the semiconductor layer 310. A distance 318 between a bottom of the polysilicon well 302 and a bottom of the non-cross-road portion 208 of the BDTI structure 206 may be greater than a distance 318 between a bottom of the polysilicon well 302 and a bottom of the cross-road portion 210 of the BDTI structure 206. The polysilicon well 302 may be configured to be electrically biased to increase hole density around the portion of the BDTI structure 206.

As indicated above, FIGS. 3A-3D are provided as an example. Other examples may differ from what is described with regard to FIGS. 3A-3D.

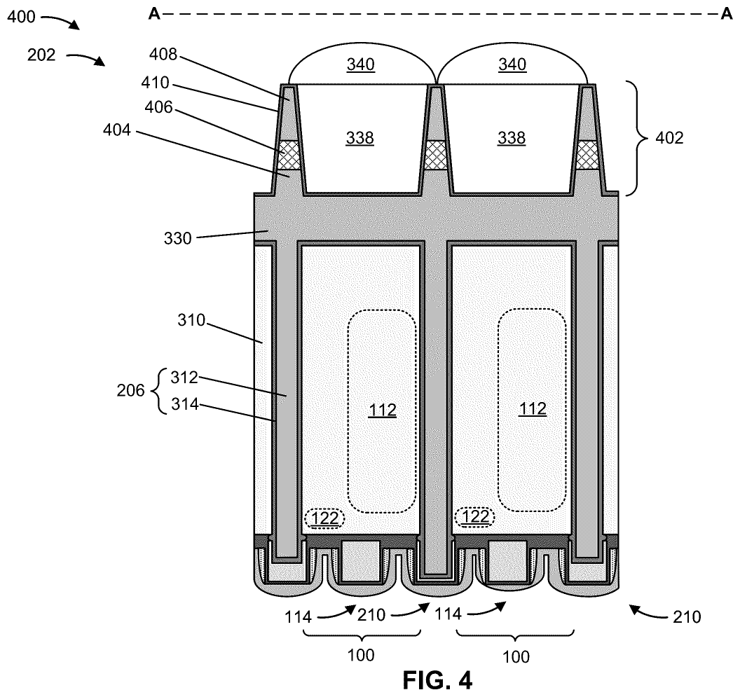

FIG. 4 is a diagram of an example implementation 400 of the pixel sensor array 202 described herein. FIG. 4 illustrates a cross-section view of the example implementation 400 of the pixel sensor array 202. The cross-section view in FIG. 4 is along the cross-section A-A of the pixel sensor array 202 in FIGS. 2A and 2B.

As shown in FIG. 3, the pixel sensor array 202 in the example implementation 400 includes a similar combination and arrangement of layers and structures as the example implementation 300 of the pixel sensor array 202. However, in the example implementation 400 of the pixel sensor array 202, the metal grid 332 is omitted, and a composite metal grid 402 is included above the buffer layer 330. The composite metal grid 402 includes a grid of intersecting columns that substantially conforms to the shape of the grid of the BDTI structure 206. The composite metal grid 402 may include a layer stack of a dielectric portion 404, a metal portion 406, and another dielectric portion 408. A liner 410 may be included over the composite metal grid 402.

The dielectric portions 404 and 408 may each include a silicon oxide (SiOₓ) (e.g., silicon dioxide (SiO₂)), a silicon nitride (SiₓN_{y}), a silicon carbide (SiCₓ), a hafnium oxide (HfOₓ), a silicon oxynitride (SiON), tetraethyl orthosilicate oxide, phosphosilicate glass (PSG), borophosphosilicate glass (BPSG), fluorinated silica glass (FSG), carbon doped silicon oxide, and/or another dielectric material. The metal portion 406 may include a similar composition of materials as the metal grid 332. The liner 410 may include a silicon oxide (SiOₓ) (e.g., silicon dioxide (SiO₂)), a silicon nitride (SiₓN_{y}), a silicon carbide (SiCₓ), a hafnium oxide (HfOₓ), a silicon oxynitride (SiON), tetraethyl orthosilicate oxide, phosphosilicate glass (PSG), borophosphosilicate glass (BPSG), fluorinated silica glass (FSG), carbon doped silicon oxide, and/or another dielectric material. As further shown in FIG. 4, the color filters 338 may be recessed in the composite metal grid 402 and may be included between the columns of the composite metal grid 402.

As indicated above, FIG. 4 is provided as an example. Other examples may differ from what is described with regard to FIG. 4.

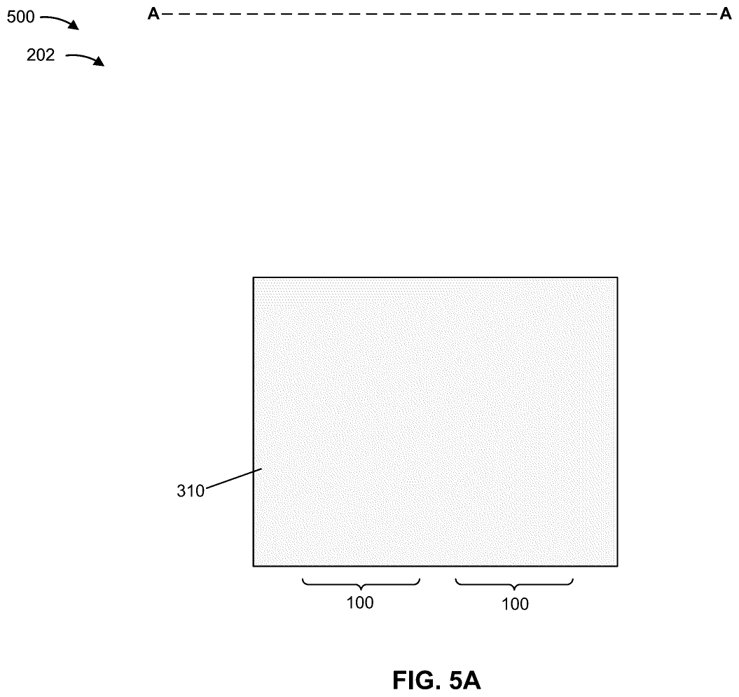

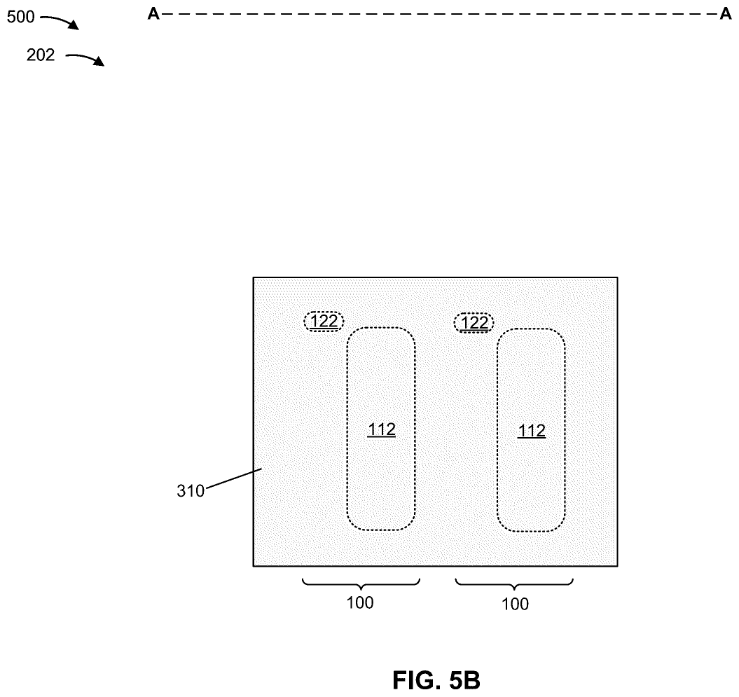

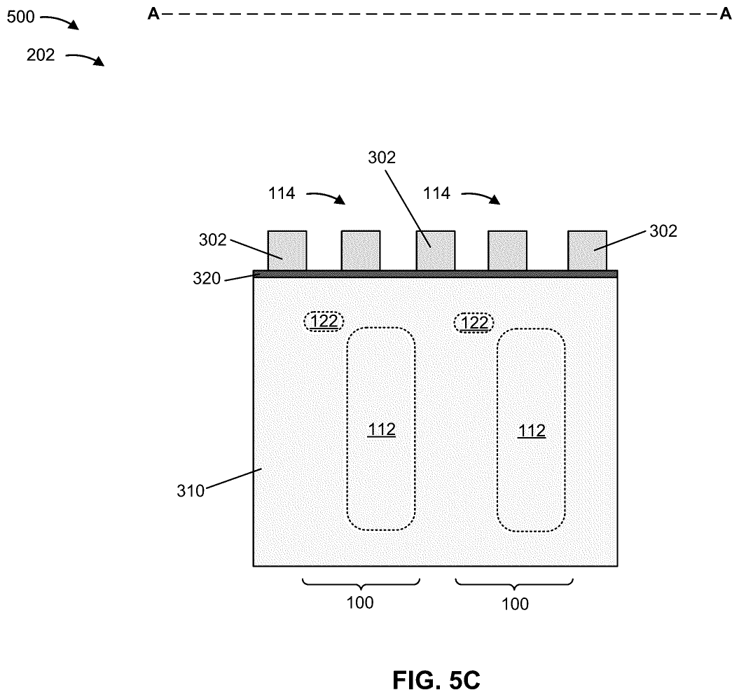

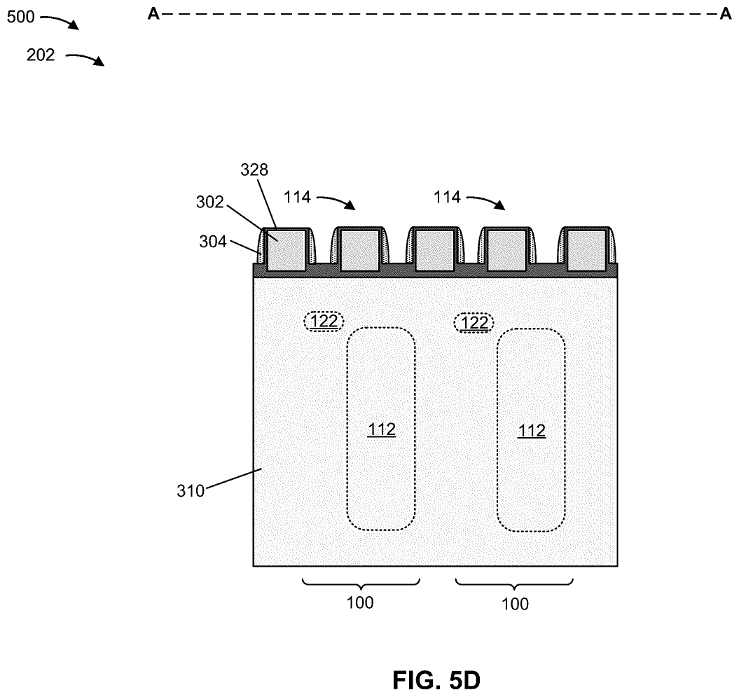

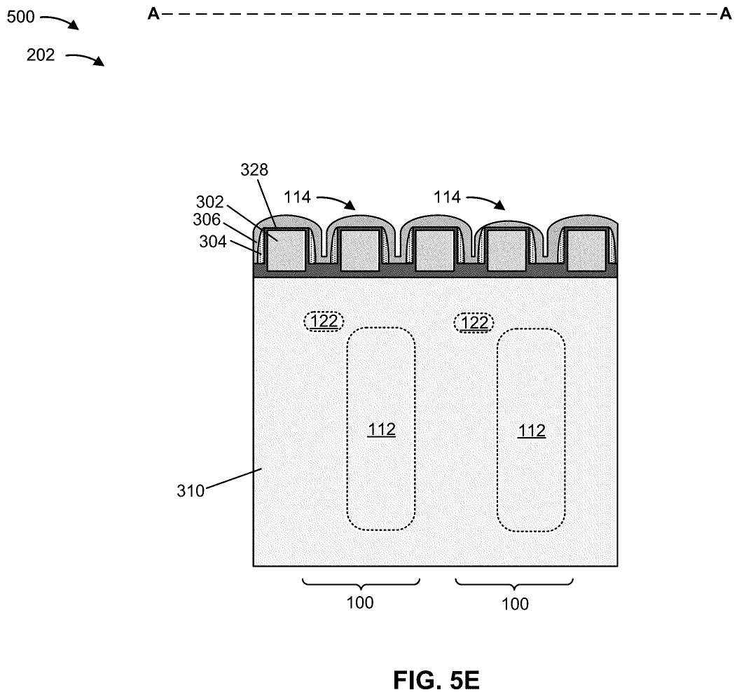

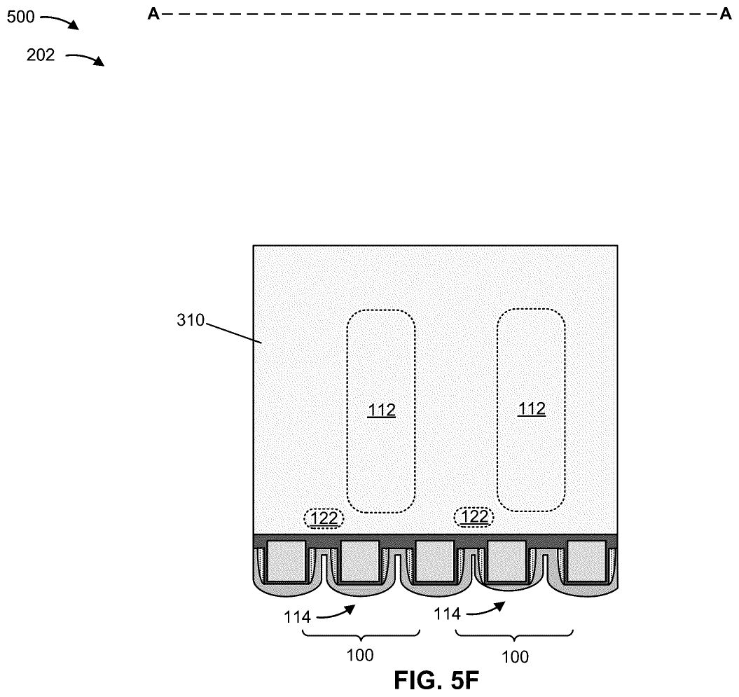

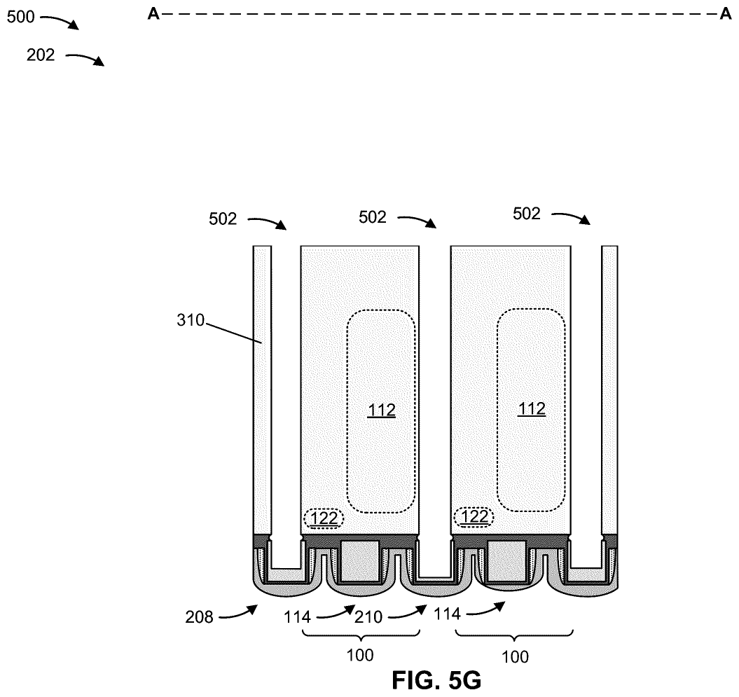

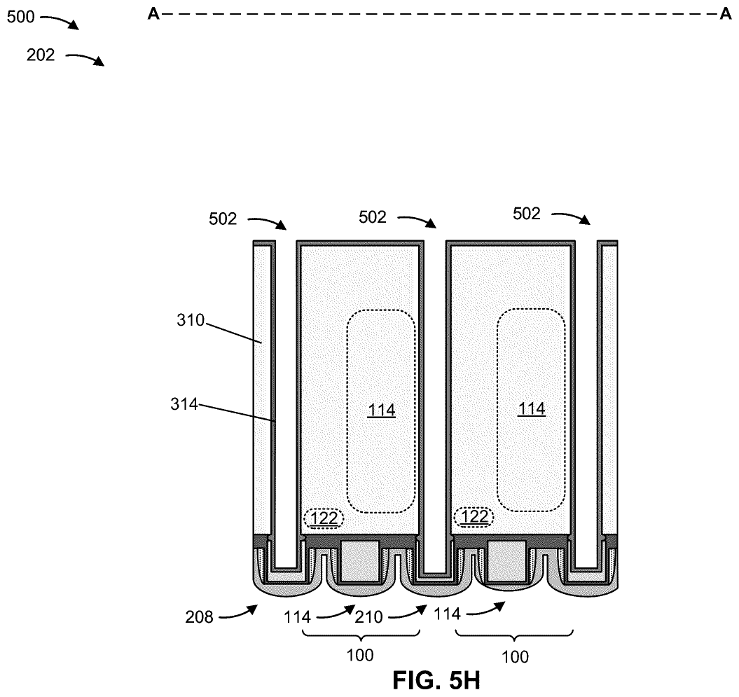

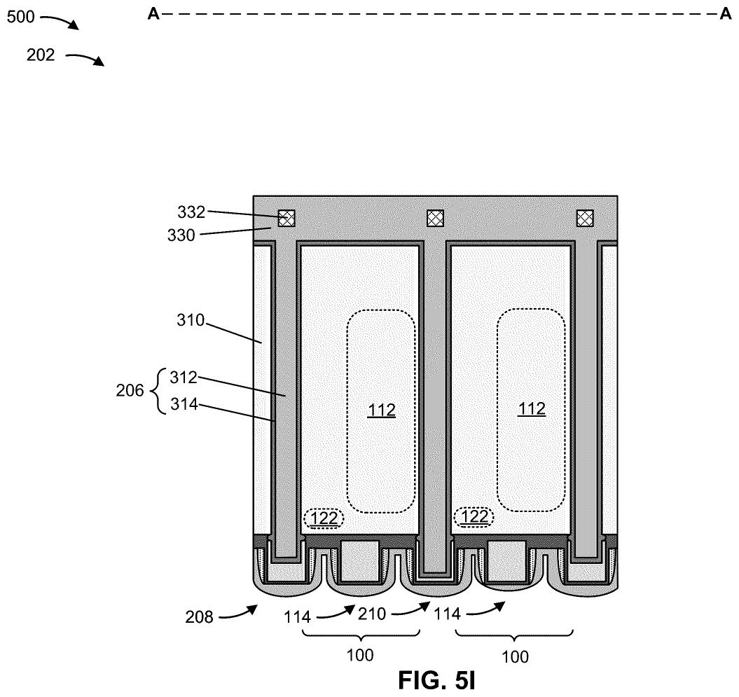

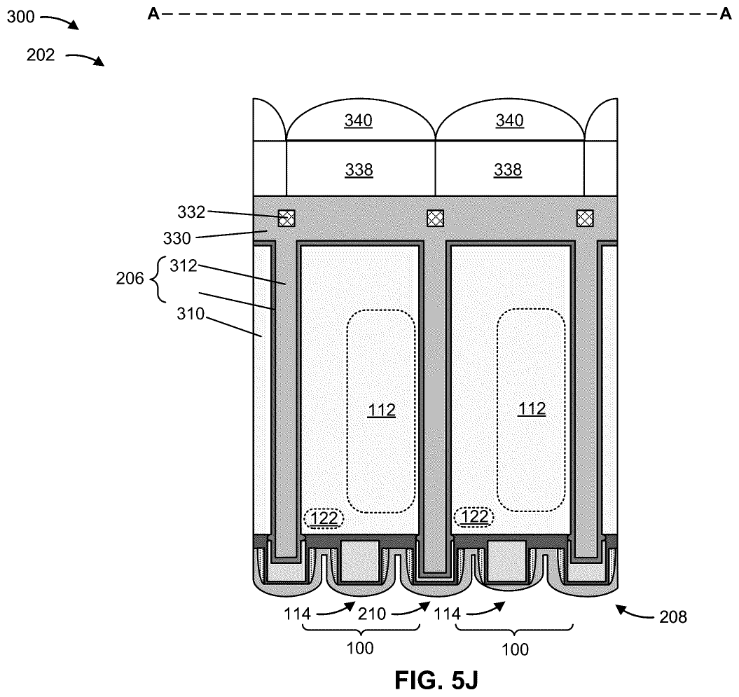

FIGS. 5A-5J are diagrams of an example implementation 500 of forming the example implementation 300 of the pixel sensor array 202 described herein. FIGS. 5A-5J illustrate cross-section views of the example implementation 500 along the cross-section A-A of the pixel sensor array 202 in FIGS. 2A and 2B. In some implementations, one or more processing operations described in connection with FIGS. 5A-5J may be performed using one or more semiconductor processing tools, such as a deposition tool, an exposure tool, a developer tool, an etch tool, a planarization tool, a plating tool, and/or an ion implantation tool, among other examples.

Turning to FIG. 5A, the example implementation 500 of forming the example implementation 300 of the pixel sensor array 202 may be performed in connection with the semiconductor layer 310. The semiconductor layer 310 may be provided as a semiconductor wafer or another type of semiconductor work piece.

As shown in FIG. 5B, a plurality of regions of the semiconductor layer 310 may be doped to form photodiodes 112 for one or more pixel sensors 100. An ion implantation tool may be used to dope the semiconductor layer 310 to form one or more n-type regions and/or one or more p-type regions of the photodiodes 112. The ion implantation tool may be used to implant p⁺ ions in the semiconductor layer 310 to form the p-type region(s) and/or may implant n⁺ ions in the semiconductor layer 310 to form the n-type region(s).

As further shown in FIG. 5B, one or more regions of the semiconductor layer 310 may be doped to form floating diffusion nodes 122 of the one or more pixel sensors 100. In some implementations, an ion implantation tool may be used to dope by implanting n⁺ ions in the semiconductor layer 310 to form the floating diffusion nodes 122.

As shown in FIG. 5C, an oxide layer 320 may be formed over and/or on the front side of the semiconductor layer 310. Moreover, the polysilicon well 302 may be formed over and/or on the oxide layer 320. Transfer gates 114 of the one or more pixel sensors 100 may be formed over and/or on the oxide layer 320. The oxide layer 320 may function as the gate oxide or gate dielectric layer for the transfer gates 114. In some implementations, the polysilicon well 302 and the transfer gates 114 are formed in the same set of one or more deposition operations. In some implementations, the polysilicon well 302 and the transfer gates 114 are formed in different deposition operations.

A deposition tool may be used to deposit the oxide layer 320 in a physical vapor deposition (PVD) operation, an atomic layer deposition (ALD) operation, a chemical vapor deposition (CVD) operation, an epitaxy operation, an oxidation operation, or another type of deposition operation. In some implementations, a planarization tool may be used to planarize the oxide layer 320 after the oxide layer 320 is deposited. A deposition tool may be used to deposit the polysilicon well 302 and the transfer gates 114 in an epitaxy operation and/or in another type of deposition operation.

As shown in FIG. 5D, the oxide layer 328 may be formed over and/or on the oxide layer 320, over and/or on the sidewalls of the polysilicon well 302, over and/or on the top surfaces of the polysilicon well 302, over and/or on the sidewalls of the transfer gates 114, and/or over and/or on the top surfaces of the transfer gates 114. The oxide layer 328 may increase the thickness of the oxide layer 320 in portions where the oxide layer 320 is not covered by the polysilicon well 302 or the transfer gates 114. Accordingly, a thickness of the oxide layer 320 under the transfer gates 114 and/or under the polysilicon well 302 may be lesser than a thickness of the oxide layer 320 between the polysilicon well 302 and/or between the transfer gates 114. A deposition tool may be used to deposit the oxide layer 328 in a PVD operation, an ALD operation, a CVD operation, an oxidation operation, an RPO operation, or another type of deposition operation.

As further shown in FIG. 5D, dielectric sidewall spacers 304 may be formed on sidewalls of the polysilicon well 302 and on sidewalls of the transfer gates 114. A deposition tool may be used to deposit the dielectric sidewall spacers 304 in a PVD operation, an ALD operation, a CVD operation, an oxidation operation, an RPO operation, or another type of deposition operation. In some implementations, a conformal layer of dielectric material is deposited, and then an etch tool is used to remove portions of the dielectric layer, where the remaining portions of the dielectric layer correspond to the dielectric sidewall spacers 304. Accordingly, the dielectric sidewall spacers 304 may have a rounded outer surface resulting from the etch operation.

As shown in FIG. 5E, the CESL 306 may be formed over and/or on the dielectric sidewall spacers 304, over the polysilicon well 302, and/or over the transfer gates 114. A deposition tool may be used to deposit the CESL 306 in a PVD operation, an ALD operation, a CVD operation, an oxidation operation, an RPO operation, or another type of deposition operation.

As shown in FIG. 5F, the semiconductor layer 310 may be flipped so that backside processing may be performed on the pixel sensor array 202.

As shown in FIG. 5G, recesses 502 may be formed from the backside surface of the semiconductor layer 310 and fully through the semiconductor layer 310 to the frontside surface of the semiconductor layer 310. Over-etching may be performed to form the recesses 502 into the polysilicon well 302 on the frontside of the semiconductor layer 310. An etch tool may be used to etch the semiconductor layer 310 and the polysilicon well 302. Moreover, the recesses 502 may be formed by etching through the oxide layer 320 between the semiconductor layer 310 and the polysilicon well 302. The lesser thickness of the oxide layer between the semiconductor layer 310 and the polysilicon well 302, in combination with the polysilicon well 302, may result in minimal lateral etching into the oxide layer 320. An etch depth into the polysilicon well 302 at the cross-road portions 210 may be greater relative to an etch depth into the polysilicon well 302 at the non-cross-road portions 208.

In some implementations, a pattern in a photoresist layer is used to pattern the recesses 502. In these implementations, a deposition tool may be used to form the photoresist layer on the backside surface of the semiconductor layer 310. An exposure tool may be used to expose the photoresist layer to a radiation source to pattern the photoresist layer. A developer tool may be used to develop and remove portions of the photoresist layer to expose the pattern. An etch tool may be used to etch the semiconductor layer 310, the oxide layer 320, and the polysilicon well 302 based on the pattern to form the recesses 502. In some implementations, the etch operation includes a plasma etch operation, a wet chemical etch operation, and/or another type of etch operation. In some implementations, a photoresist removal tool may be used to remove the remaining portions of the photoresist layer (e.g., using a chemical stripper, plasma ashing, and/or another technique). Alternatively, the pattern in the photoresist layer may be used to transfer the pattern to a hard mask layer that is used for forming 502.

As shown in FIG. 5H, the dielectric liner 314 may be formed on sidewalls and on bottom surfaces of the recesses 502. A deposition tool may be used to conformally deposit the dielectric liner 314 in a PVD operation, an ALD operation, a CVD operation, and/or another type of deposition operation. The dielectric liner 314 may further be deposited on the backside surface of the semiconductor layer 310. In some implementations, the dielectric liner 314 is subsequently removed from the backside surface of the semiconductor layer 310. In some implementations, the dielectric liner 314 remains on the backside surface of the semiconductor layer 310 (e.g., as an antireflective coating).

As shown in FIG. 5I, the recesses 502 may be filled with a dielectric material 312 (e.g., an oxide-containing dielectric material, a high-k dielectric material) over the dielectric liner 314 to form the BDTI structure 206 in the recesses 502. The BDTI structure 206 may extend into the polysilicon well 302.

As further shown in FIG. 5I, the dielectric material 312 may be deposited over the backside surface of the semiconductor layer 310 to form the buffer layer 330. Moreover, the metal grid 332 may be formed in the buffer layer 330. For example, a first portion of the buffer layer 330 may be deposited, recesses may be etched in the first portion of the buffer layer 330, and the metal grid 332 may be formed in the recesses. The remaining portion of the buffer layer 330 may then be deposited over the first portion and over the metal grid 332.

A deposition tool may be used to deposit the dielectric material 312 in the recesses to form the BDTI structure 206 in a PVD operation, an ALD operation, a CVD operation, an oxidation operation, and/or another type of deposition operation. A deposition tool may be used to deposit the buffer layer 330 in a PVD operation, an ALD operation, a CVD operation, an oxidation operation, and/or another type of deposition operation. In some implementations, a planarization tool may be used to planarize the buffer layer 330 after the buffer layer 330 is deposited. A deposition tool and/or a plating tool may be used to deposit the metal grid 332 in a CVD operation, a PVD operation, an ALD operation, an electroplating operation, and/or another deposition operation. In some implementations, a seed layer is first deposited, and the metal grid 332 is deposited on the seed layer. In some implementations, a planarization tool may be used to planarize the metal grid 332 after the metal grid 332 is deposited.

As further shown in FIG. 5J, the color filters 338 and micro-lenses 340 may be formed over and/or on the buffer layer 330.

As indicated above, FIGS. 5A-5J are provided as an example. Other examples may differ from what is described with regard to FIGS. 5A-5J.

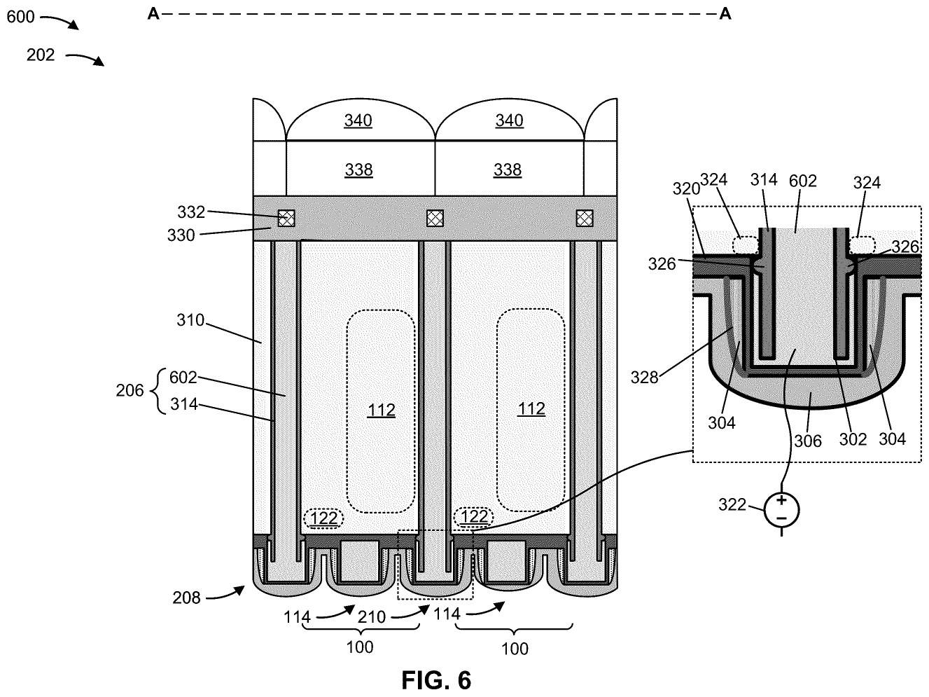

FIG. 6 is a diagram of an example implementation 600 of the pixel sensor array 202 described herein. FIG. 6 illustrates a cross-section view of the example implementation 600 of the pixel sensor array 202. The cross-section view in FIG. 6 is along the cross-section A-A of the pixel sensor array 202 in FIGS. 2A and 2B.

As shown in FIG. 6, the pixel sensor array 202 in the example implementation 600 includes a similar combination and arrangement of layers and structures as the example implementation 300 of the pixel sensor array 202. However, in the example implementation 600 of the pixel sensor array 202, the bottom portions of the dielectric liner 314 of the BDTI structure 206 are omitted. Moreover, a polysilicon material 602 is included in the BDTI structure 206 instead of the dielectric material 312. The polysilicon material 602 (e.g., polysilicon trench structures) is in direct contact with the polysilicon well 302. This enables the entire BDTI structure 206 to be electrically biased to further passivate damage to the semiconductor layer 310 that might have occurred during formation of the BDTI structure 206. The BDTI structure 206 may be electrically biased through the polysilicon well 302. For example, the voltage bias 322 may be applied to the BDTI structure 206 through the polysilicon well 302 to electrically bias the BDTI structure 206. This may further reduce the dark current of the pixel sensor 100.

In some implementations, the dielectric liner 314 includes a high-k dielectric material, which may have a greater hole density than an oxide-containing dielectric material. This may enable enhanced negative biasing of the polysilicon material 602 and may reduce interface capacitance for the BDTI structure 206. In some implementations, the dielectric liner 314 includes an oxide-containing dielectric material, which may provide enhanced optical performance such as reduced light tunneling relative to high-k dielectric materials because of being able to be formed thicker than high-k dielectric material liners.

As indicated above, FIG. 6 is provided as an example. Other examples may differ from what is described with regard to FIG. 6.

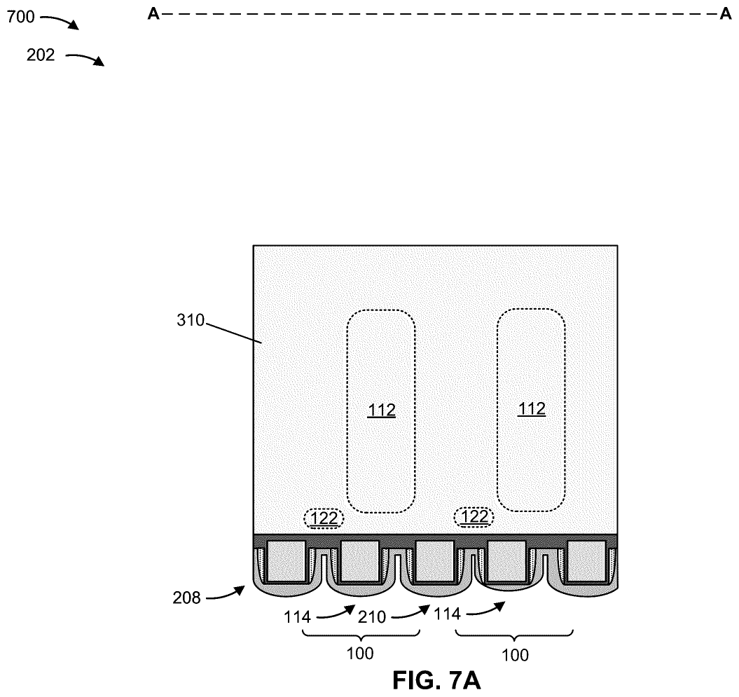

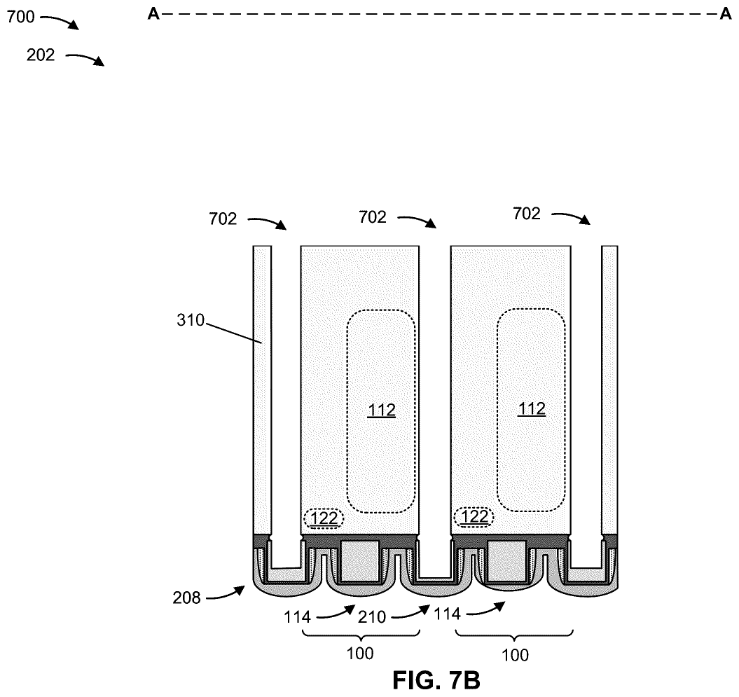

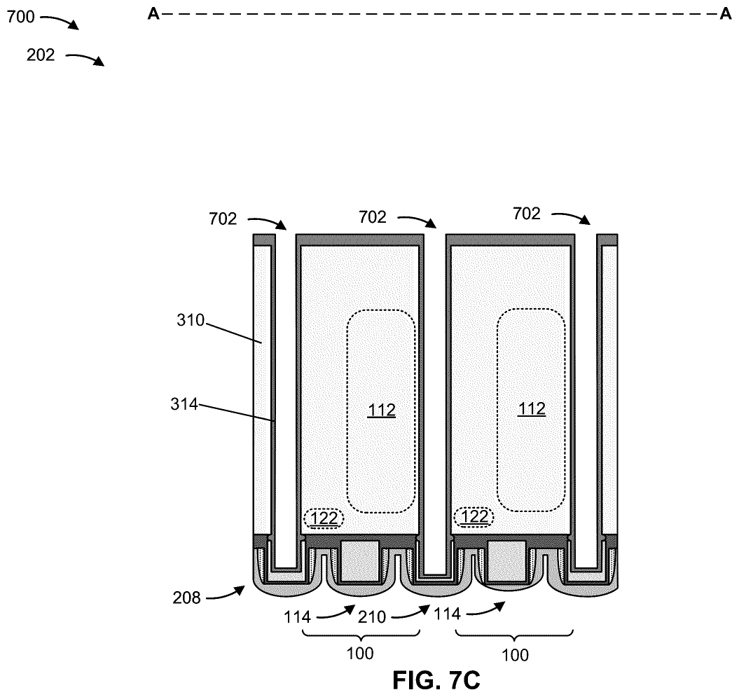

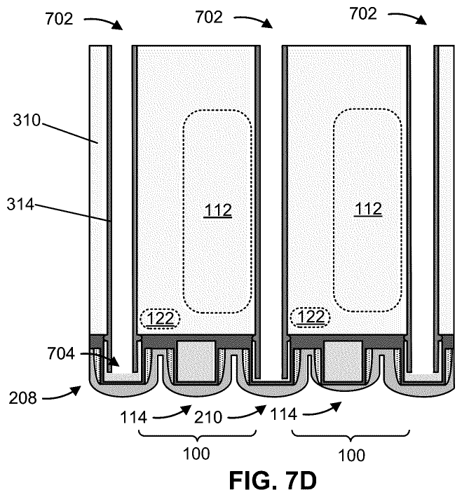

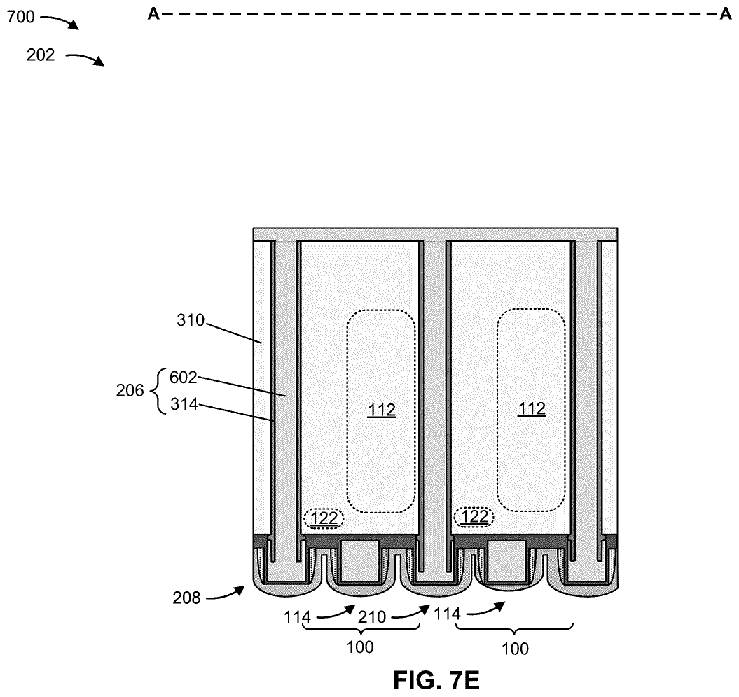

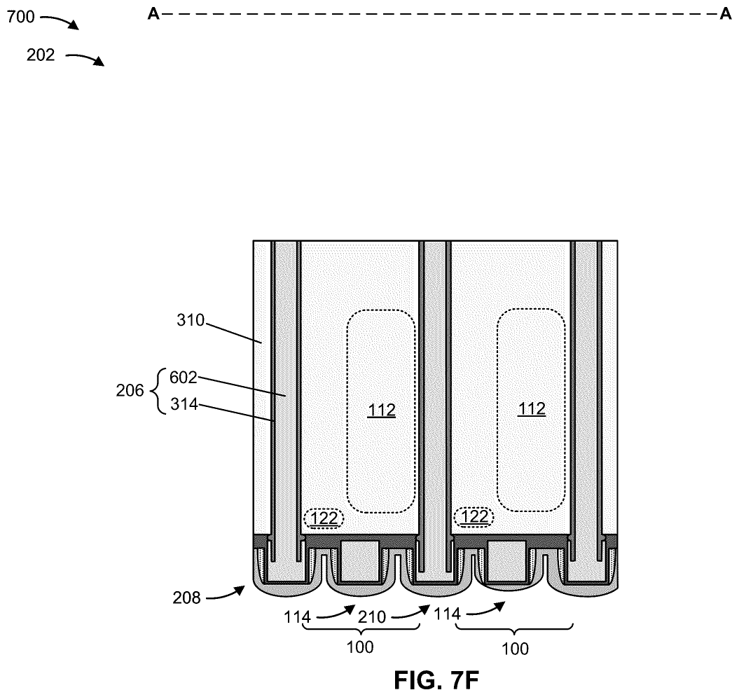

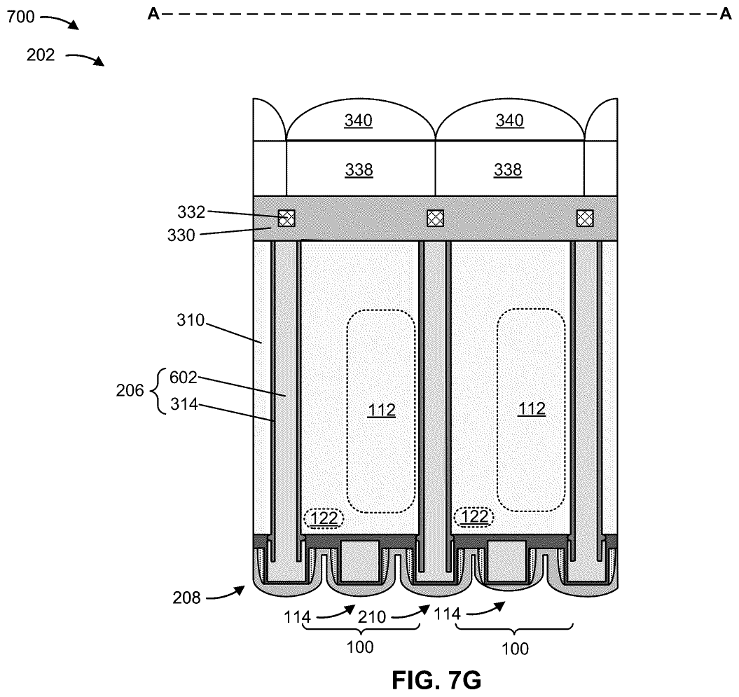

FIGS. 7A-7G are diagrams of an example implementation 700 of forming the example implementation 600 of the pixel sensor array 202 described herein. FIGS. 7A-7G illustrate cross-section views of the example implementation 700 along the cross-section A-A of the pixel sensor array 202 in FIGS. 2A and 2B. In some implementations, one or more processing operations described in connection with FIGS. 7A-7G may be performed using one or more semiconductor processing tools, such as a deposition tool, an exposure tool, a developer tool, an etch tool, a planarization tool, a plating tool, and/or an ion implantation tool, among other examples.

As shown in FIG. 7A, frontside semiconductor processing operations similar to those illustrated and described in connection with FIGS. 5A-5E may be performed for the pixel sensor array 202. The semiconductor layer 310 may be flipped so that backside processing may be performed on the pixel sensor array 202.

As shown in FIG. 7B, recesses 702 may be formed from the backside surface of the semiconductor layer 310 and fully through the semiconductor layer 310 to the frontside surface of the semiconductor layer 310. Over-etching may be performed to form the recesses 702 into the polysilicon well 302 on the frontside of the semiconductor layer 310. An etch tool may be used to etch the semiconductor layer 310 and the polysilicon well 302. Moreover, the recesses 702 may be formed by etching through the oxide layer 320 between the semiconductor layer 310 and the polysilicon well 302. The lesser thickness of the oxide layer between the semiconductor layer 310 and the polysilicon well 302, in combination with the polysilicon well 302, may result in minimal lateral etching into the oxide layer 320. An etch depth into the polysilicon well 302 at the cross-road portions 210 may be greater relative to an etch depth into the polysilicon well 302 at the non-cross-road portions 208.

In some implementations, a pattern in a photoresist layer is used to pattern the recesses 702. In these implementations, a deposition tool may be used to form the photoresist layer on the backside surface of the semiconductor layer 310. An exposure tool may be used to expose the photoresist layer to a radiation source to pattern the photoresist layer. A developer tool may be used to develop and remove portions of the photoresist layer to expose the pattern. An etch tool may be used to etch the semiconductor layer 310, the oxide layer 320, and the polysilicon well 302 based on the pattern to form the recesses 702. In some implementations, the etch operation includes a plasma etch operation, a wet chemical etch operation, and/or another type of etch operation. In some implementations, a photoresist removal tool may be used to remove the remaining portions of the photoresist layer (e.g., using a chemical stripper, plasma ashing, and/or another technique). Alternatively, the pattern in the photoresist layer may be used to transfer the pattern to a hard mask layer that is used for forming 702.

As shown in FIG. 7C, the dielectric liner 314 may be formed on sidewalls and on bottom surfaces of the recesses 702. A deposition tool may be used to conformally deposit the dielectric liner 314 in a PVD operation, an ALD operation, a CVD operation, and/or another type of deposition operation. The dielectric liner 314 may further be deposited on the backside surface of the semiconductor layer 310. The thickness of the dielectric liner 314 formed on the backside surface of the semiconductor layer 310 may be greater than the thickness of the dielectric liner 314 formed on the bottom surface of the recesses 702. This enables the dielectric liner 314 to protect the backside surface of the semiconductor layer 310 from etch damage when etching through the dielectric liner 314 on the bottom surface of the recesses 702 to expose the polysilicon well 302 through the recesses 702.

As shown in FIG. 7D, an etch back operation may be performed to remove the portions of the dielectric liner 314 from the bottom surface 704 of the recesses 702 to expose the polysilicon well 302 through the recesses 702. As indicated above, the thickness of the dielectric liner 314 formed on the backside surface of the semiconductor layer 310 may be greater than the thickness of the dielectric liner 314 formed on the bottom surface 704 of the recesses 702. This enables the dielectric liner 314 to be fully removed from the bottom surface 704 of the recesses 702 before the dielectric liner 314 on the backside surface of the semiconductor layer 310 is fully consumed. This enables the dielectric liner 314 to protect the backside surface of the semiconductor layer 310 from etch damage when etching through the dielectric liner 314 on the bottom surface 704 of the recesses 702 to expose the polysilicon well 302 through the recesses 702. In some implementations, an etch tool may be used to perform a dry etch for the etch back operation. For example, the etch back operation may include a highly-directional plasma etch that is performed to remove material from the dielectric liner 314 on the bottom surface 704 of the recesses 702 while minimizing removal of material from the dielectric liner 314 on the sidewalls of the recesses 702. However, other etch techniques may be performed to remove material from the dielectric liner 314 on the bottom surface 704 of the recesses 702.

As shown in FIG. 7E, the recesses 702 may be filled with a polysilicon material 602 over the dielectric liner 314 to form the BDTI structure 206 in the recesses 702. The polysilicon material 602 may extend into the polysilicon well 302 and may land on the polysilicon well 302 through the openings etched into the bottom surfaces 704 of the recesses 702. A deposition tool may be used to deposit the polysilicon material 602 in an epitaxy operation and/or in another type of deposition operation.

As further shown in FIG. 7F, polysilicon material 602 on the backside surface of the semiconductor layer 310 may be removed in a planarization operation. A planarization tool may be used to perform the planarization operation, such as a chemical mechanical planarization (CMP) operation.

As shown in FIG. 7G, dielectric material may be deposited over the backside surface of the semiconductor layer 310 to form the buffer layer 330. Moreover, the metal grid 332 may be formed in the buffer layer 330. For example, a first portion of the buffer layer 330 may be deposited, recesses may be etched in the first portion of the buffer layer 330, and the metal grid 332 may be formed in the recesses. The remaining portion of the buffer layer 330 may then be deposited over the first portion and over the metal grid 332.

A deposition tool may be used to deposit the buffer layer 330 in a PVD operation, an ALD operation, a CVD operation, an oxidation operation, and/or another type of deposition operation. In some implementations, a planarization tool may be used to planarize the buffer layer 330 after the buffer layer 330 is deposited. A deposition tool and/or a plating tool may be used to deposit the metal grid 332 in a CVD operation, a PVD operation, an ALD operation, an electroplating operation, and/or another deposition operation. In some implementations, a seed layer is first deposited, and the metal grid 332 is deposited on the seed layer. In some implementations, a planarization tool may be used to planarize the metal grid 332 after the metal grid 332 is deposited. The color filters 338 and micro-lenses 340 may be formed over and/or on the buffer layer 330.

As indicated above, FIGS. 7A-7G are provided as an example. Other examples may differ from what is described with regard to FIGS. 7A-7G.

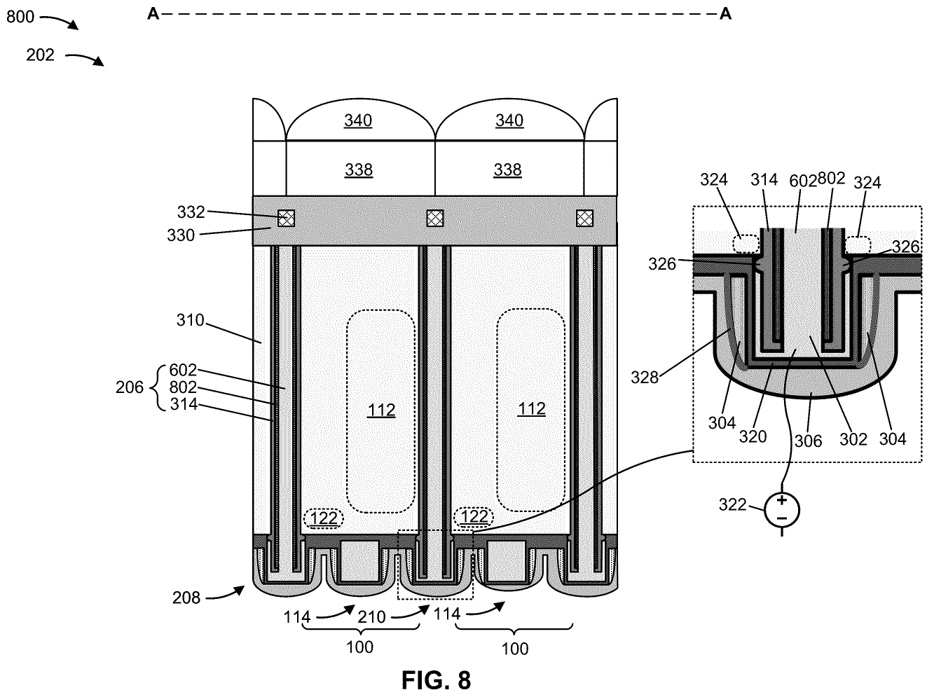

FIG. 8 is a diagram of an example implementation 800 of the pixel sensor array 202 described herein. FIG. 8 illustrates a cross-section view of the example implementation 800 of the pixel sensor array 202. The cross-section view in FIG. 8 is along the cross-section A-A of the pixel sensor array 202 in FIGS. 2A and 2B.

As shown in FIG. 8, the pixel sensor array 202 in the example implementation 800 includes a similar combination and arrangement of layers and structures as the example implementation 600 of the pixel sensor array 202. However, in the example implementation 800 of the pixel sensor array 202, the BDTI structure 206 includes a plurality of liners, including a dielectric liner 314 and a dielectric liner 802. The dielectric liner 314 may be included between the dielectric liner 802 and the semiconductor layer 310. The dielectric liner 802 may be included between the polysilicon material 602 and the dielectric liner 314. The dielectric liner 314 may include a high-k dielectric material, and the dielectric liner 802 may include an oxide-containing dielectric material. The combination of the high-k dielectric liner and the oxide-containing liner enables a combination of enhanced optical performance (e.g., reduced light tunneling from the oxide-containing dielectric liner) and enhanced damage passivation (e.g., increased negative biasing due to the greater hole density in the high-k dielectric liner) to be achieved for the BDTI structure 206.

As indicated above, FIG. 8 is provided as an example. Other examples may differ from what is described with regard to FIG. 8.

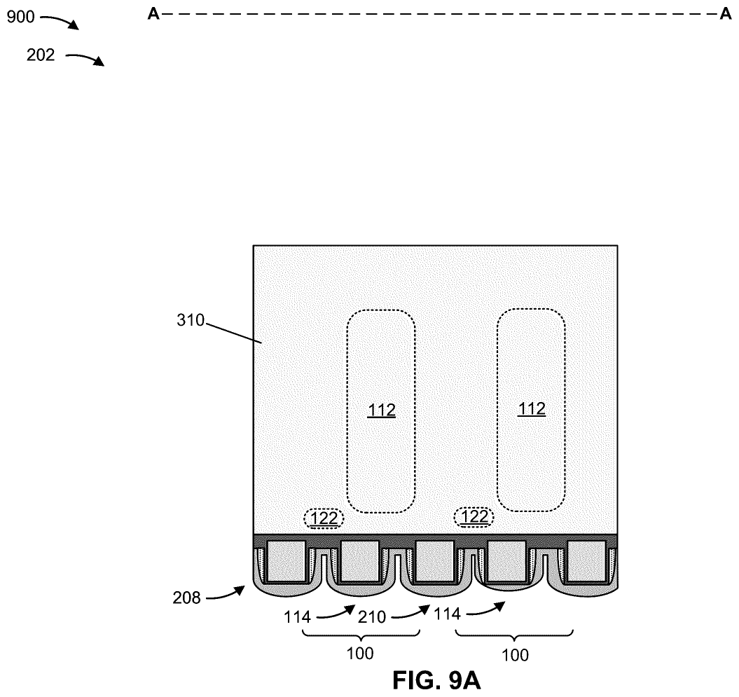

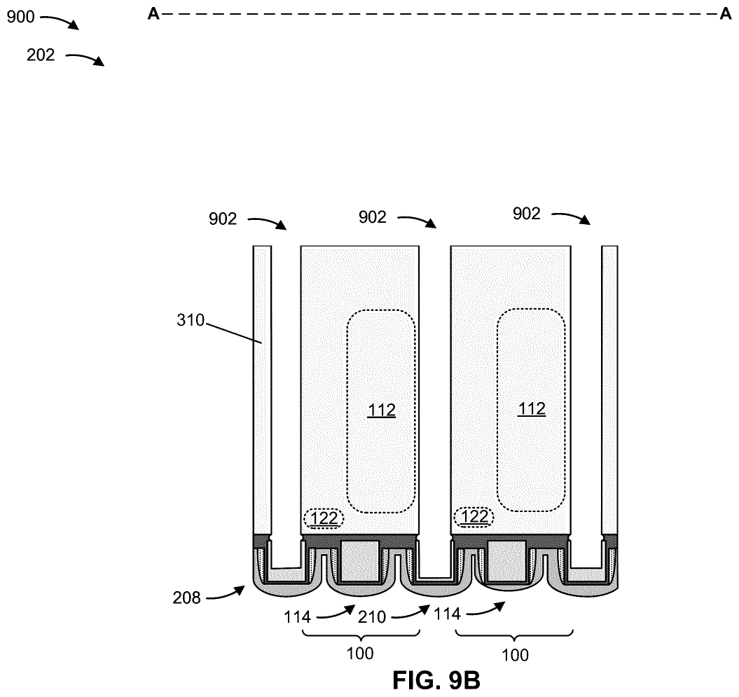

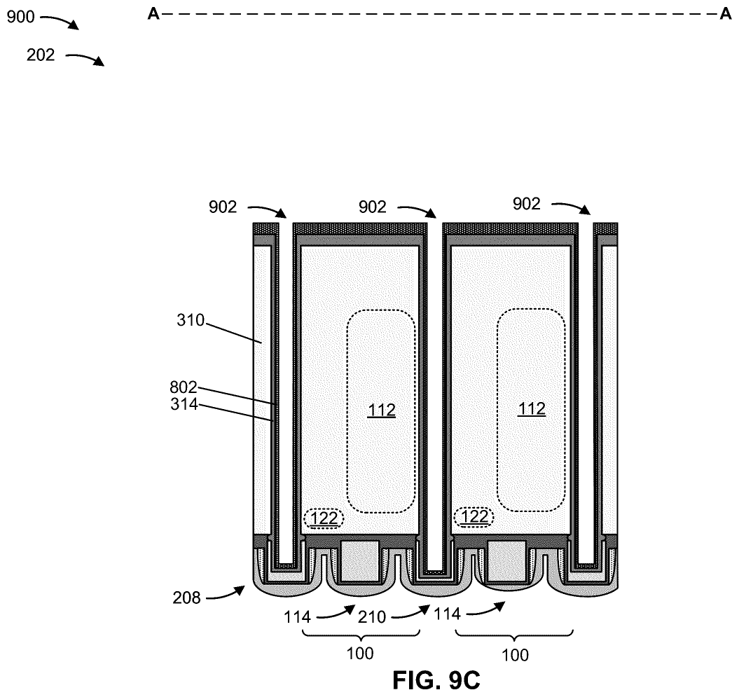

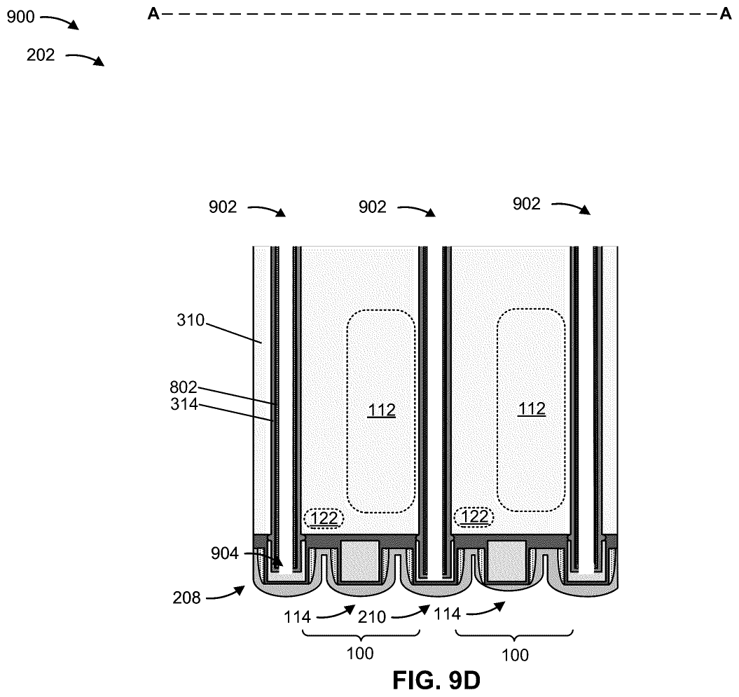

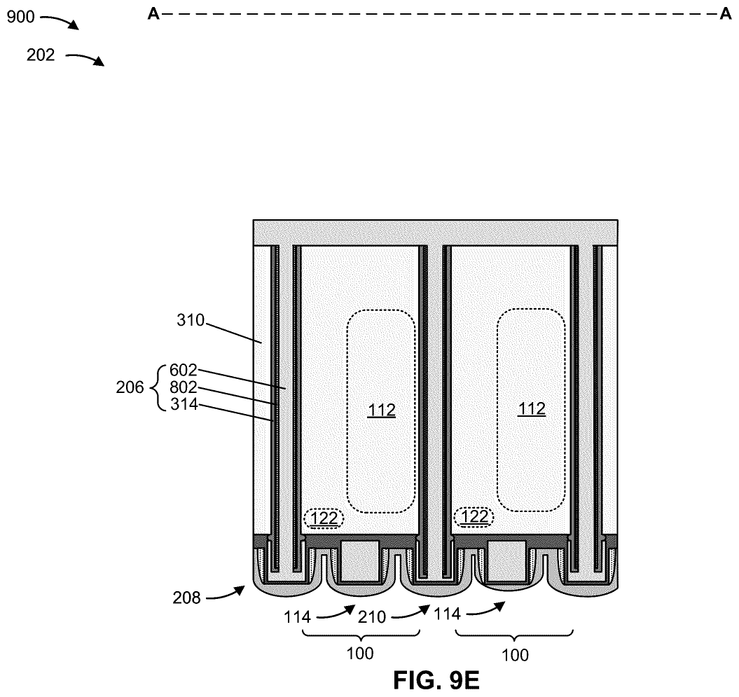

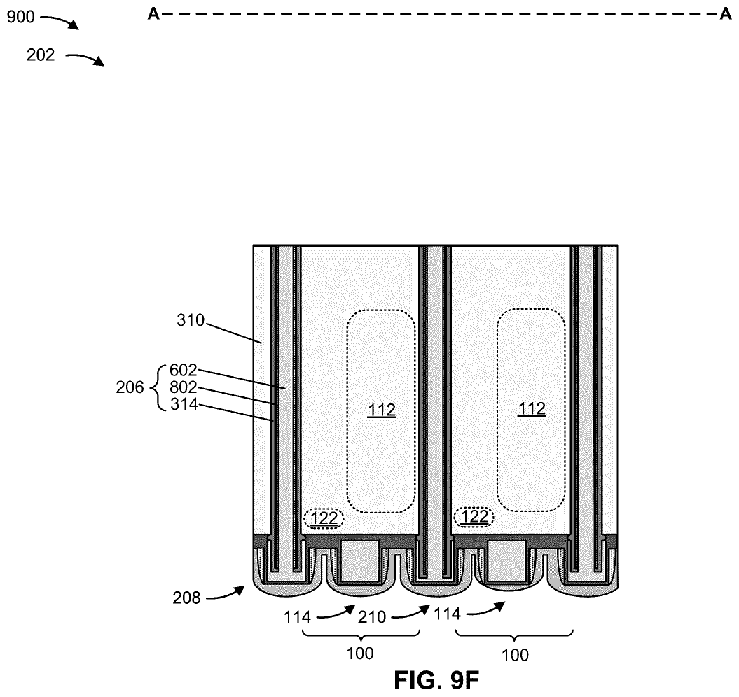

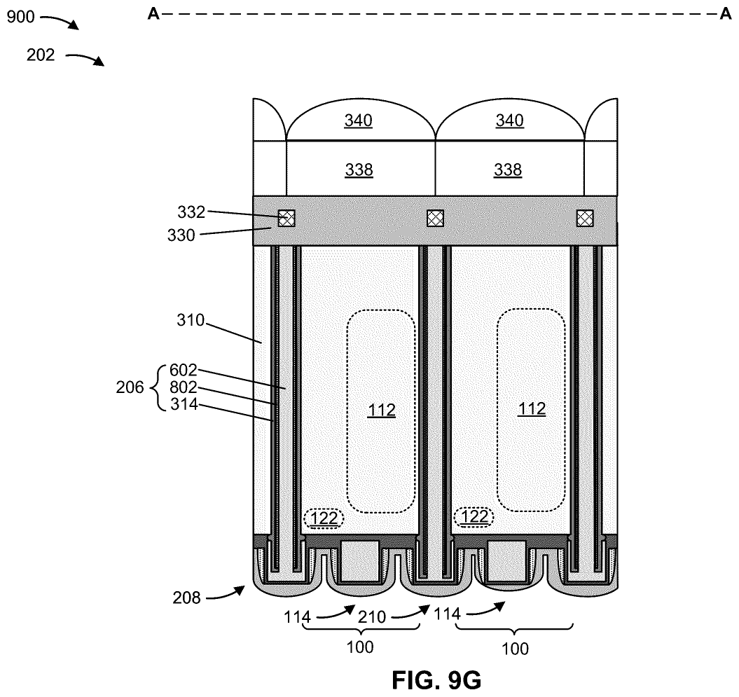

FIGS. 9A-9G are diagrams of an example implementation 900 of forming the example implementation 800 of the pixel sensor array 202 described herein. FIGS. 9A-9G illustrate cross-section views of the example implementation 900 along the cross-section A-A of the pixel sensor array 202 in FIGS. 2A and 2B. In some implementations, one or more processing operations described in connection with FIGS. 9A-9G may be performed using one or more semiconductor processing tools, such as a deposition tool, an exposure tool, a developer tool, an etch tool, a planarization tool, a plating tool, and/or an ion implantation tool, among other examples.

As shown in FIG. 9A, frontside semiconductor processing operations similar to those illustrated and described in connection with FIGS. 5A-5E may be performed for the pixel sensor array 202. The semiconductor layer 310 may be flipped so that backside processing may be performed on the pixel sensor array 202.

As shown in FIG. 9B, recesses 902 may be formed from the backside surface of the semiconductor layer 310 and fully through the semiconductor layer 310 to the frontside surface of the semiconductor layer 310. Over-etching may be performed to form the recesses 902 into the polysilicon well 302 on the frontside of the semiconductor layer 310. An etch tool may be used to etch the semiconductor layer 310 and the polysilicon well 302. Moreover, the recesses 902 may be formed by etching through the oxide layer 320 between the semiconductor layer 310 and the polysilicon well 302. The lesser thickness of the oxide layer between the semiconductor layer 310 and the polysilicon well 302, in combination with the polysilicon well 302, may result in minimal lateral etching into the oxide layer 320. An etch depth into the polysilicon well 302 at the cross-road portions 210 may be greater relative to an etch depth into the polysilicon well 302 at the non-cross-road portions 208.

In some implementations, a pattern in a photoresist layer is used to pattern the recesses 902. In these implementations, a deposition tool may be used to form the photoresist layer on the backside surface of the semiconductor layer 310. An exposure tool may be used to expose the photoresist layer to a radiation source to pattern the photoresist layer. A developer tool may be used to develop and remove portions of the photoresist layer to expose the pattern. An etch tool may be used to etch the semiconductor layer 310, the oxide layer 320, and the polysilicon well 302 based on the pattern to form the recesses 902. In some implementations, the etch operation includes a plasma etch operation, a wet chemical etch operation, and/or another type of etch operation. In some implementations, a photoresist removal tool may be used to remove the remaining portions of the photoresist layer (e.g., using a chemical stripper, plasma ashing, and/or another technique). Alternatively, the pattern in the photoresist layer may be used to transfer the pattern to a hard mask layer that is used for forming the recesses 902.

As shown in FIG. 9C, the dielectric liners 314 and 802 may be formed on sidewalls and on bottom surfaces of the recesses 902. For example, the dielectric liner 314 may be formed directly on the sidewalls and directly on the bottom surfaces of the recesses 902, and the dielectric liner 802 may be formed on the sidewalls and on the bottom surfaces on the dielectric liner 314. A deposition tool may be used to conformally deposit the dielectric liner 314 in a PVD operation, an ALD operation, a CVD operation, and/or another type of deposition operation. A deposition tool may be used to conformally deposit the dielectric liner 802 in a PVD operation, an ALD operation, a CVD operation, and/or another type of deposition operation. The dielectric liners 314 and 802 may further be deposited on the backside surface of the semiconductor layer 310. A combination of a thickness of the dielectric liner 314 and a thickness of the dielectric liner 802 formed on the backside surface of the semiconductor layer 310 may be greater than a combination of a thickness of the dielectric liner 314 and a thickness of the dielectric liner 802 formed on the bottom surface of the recesses 902. This enables the dielectric liners 314 and 802 to protect the backside surface of the semiconductor layer 310 from etch damage when etching through the dielectric liners 314 and 802 on the bottom surface of the recesses 902 to expose the polysilicon well 302 through the recesses 902.

As shown in FIG. 9D, an etch back operation may be performed to remove the portions of the dielectric liners 314 and 802 from the bottom surface 904 of the recesses 902 to expose the polysilicon well 302 through the recesses 902. As indicated above, the combination of the thickness of the dielectric liner 314 and the thickness of the dielectric liner 802 formed on the backside surface of the semiconductor layer 310 may be greater than the combination of the thickness of the dielectric liner 314 and the thickness of the dielectric liner 802 formed on the bottom surface 904 of the recesses 902. This enables the dielectric liners 314 and 802 to be fully removed from the bottom surface 904 of the recesses 902 before the dielectric liners 314 and 802 on the backside surface of the semiconductor layer 310 is fully consumed. This enables the dielectric liners 314 and 802 to protect the backside surface of the semiconductor layer 310 from etch damage when etching through the dielectric liners 314 and 802 on the bottom surface 904 of the recesses 902 to expose the polysilicon well 302 through the recesses 902. In some implementations, an etch tool may be used to perform a dry etch for the etch back operation. For example, the etch back operation may include a highly-directional plasma etch that is performed to remove material from the dielectric liners 314 and 802 on the bottom surface 904 of the recesses 902 while minimizing removal of material from the dielectric liners 314 and 802 on the sidewalls of the recesses 902. However, other etch techniques may be performed to remove material from the dielectric liner 314 on the bottom surface 904 of the recesses 902.

As shown in FIG. 9E, the recesses 902 may be filled with a polysilicon material 602 over the dielectric liners 314 and 802 to form the BDTI structure 206 in the recesses 902. The polysilicon material 602 may extend into the polysilicon well 302 and may land on the polysilicon well 302 through the openings etched into the bottom surfaces 904 of the recesses 902. A deposition tool may be used to deposit the polysilicon material 602 in an epitaxy operation and/or in another type of deposition operation.

As further shown in FIG. 9F, polysilicon material 602 on the backside surface of the semiconductor layer 310 may be removed in a planarization operation. A planarization tool may be used to perform the planarization operation, such as a CMP operation.

As shown in FIG. 9G, dielectric material may be deposited over the backside surface of the semiconductor layer 310 to form the buffer layer 330. Moreover, the metal grid 332 may be formed in the buffer layer 330. For example, a first portion of the buffer layer 330 may be deposited, recesses may be etched in the first portion of the buffer layer 330, and the metal grid 332 may be formed in the recesses. The remaining portion of the buffer layer 330 may then be deposited over the first portion and over the metal grid 332.

A deposition tool may be used to deposit the buffer layer 330 in a PVD operation, an ALD operation, a CVD operation, an oxidation operation, or another type of deposition operation. In some implementations, a planarization tool may be used to planarize the buffer layer 330 after the buffer layer 330 is deposited. A deposition tool and/or a plating tool may be used to deposit the metal grid 332 in a CVD operation, a PVD operation, an ALD operation, an electroplating operation, and/or another deposition operation. In some implementations, a seed layer is first deposited, and the metal grid 332 is deposited on the seed layer. In some implementations, a planarization tool may be used to planarize the metal grid 332 after the metal grid 332 is deposited. The color filters 338 and micro-lenses 340 may be formed over and/or on the buffer layer 330.

As indicated above, FIGS. 9A-9G are provided as an example. Other examples may differ from what is described with regard to FIGS. 9A-9G.

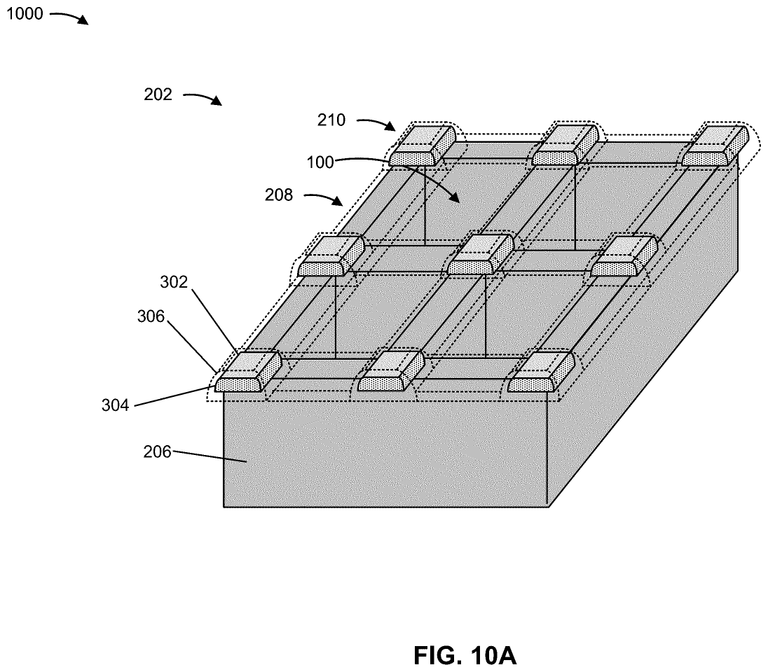

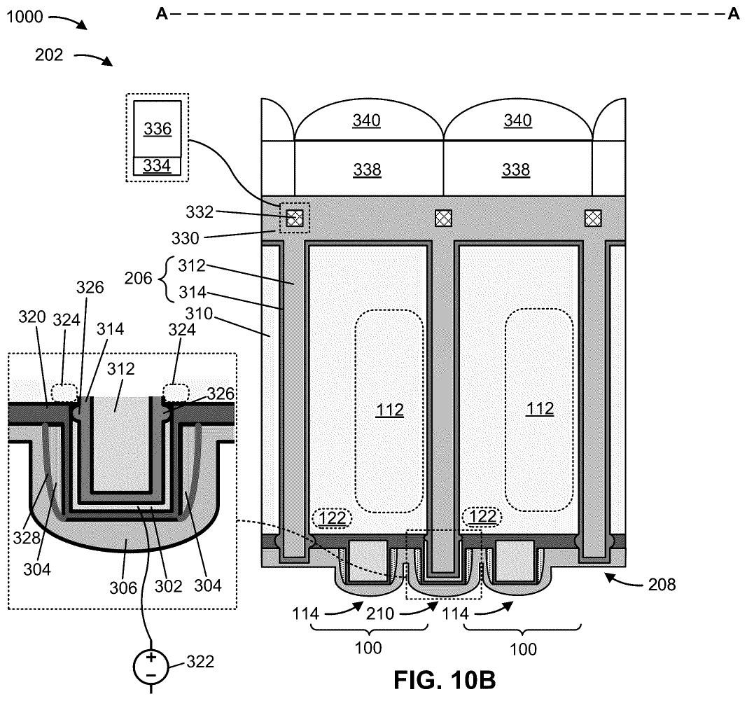

FIGS. 10A and 10B are diagrams of an example implementation 1000 of the pixel sensor array 202 described herein. FIG. 10A illustrates a perspective view of the example implementation 1000 of the pixel sensor array 202. FIG. 10B illustrates a cross-section view of the example implementation 1000 of the pixel sensor array 202. The cross-section view in FIG. 10B is along the cross-section A-A of the pixel sensor array 202 in FIGS. 2A and 2B.

As shown in FIGS. 10A and 10B, the pixel sensor array 202 in the example implementation 1000 includes a similar combination and arrangement of layers and structures as the example implementation 300 of the pixel sensor array 202. However, in the example implementation 1000 of the pixel sensor array 202, the polysilicon well 302 and the dielectric sidewall spacers 304 are omitted from the non-cross-road portions 208 of the BDTI structure 206. Instead, polysilicon wells 302 and associated dielectric sidewall spacers 304 are included only in the cross-road portions 210. The CESL 306 may still be included over both of the non-cross road portions 208 and cross-road portions 210. This may reduce the polysilicon well density in the pixel sensor array 202, which may enable a greater density of polysilicon devices to be formed in the pixel sensor array 202 (e.g., because of less poly-to-poly constraint in the pixel sensor array 202). Moreover, the polysilicon wells 302 may be omitted from the non-cross-road portions 208 in that less lateral etching occurs in the non-cross-road portions 208 than in the cross-road portions 210 due to the lesser etch rate in the non-cross-road portions 208 than in the cross-road portions 210. Thus, the non-cross-road portions 208 may be less susceptible to etch damage of the semiconductor layer 310 in the non-cross-road portions 208 than in the cross-road portions 210. Therefore, the polysilicon wells 302 may be included only in the cross-road portions 210.

In this way, the pixel sensor array 202 includes a plurality of pixel sensors 100 and a BDTI structure 206 surrounding the plurality of pixel sensors 100. The BDTI structure 206 fully extends through the semiconductor layer 310 of the pixel sensor array 202 between a front side of the semiconductor layer 310 and a backside of the semiconductor layer 310. The BDTI structure 206 extends into and/or is surrounded by a polysilicon well 302 under the semiconductor layer 310 at a cross-road portion 210 of the BDTI structure 206 and not at a non-cross-road portion 208. A non-cross-road portion 208 of the BDTI structure 206, between two pixel sensors 100 of the plurality of pixel sensors 100, may extend into a portion of the CESL 306.

As indicated above, FIGS. 10A and 10B are provided as an example. Other examples may differ from what is described with regard to FIGS. 10A and 10B.

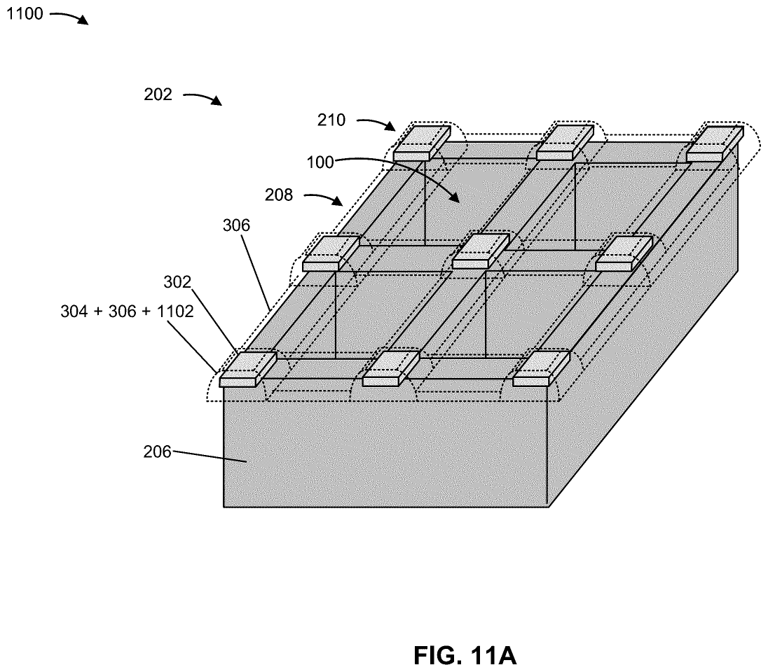

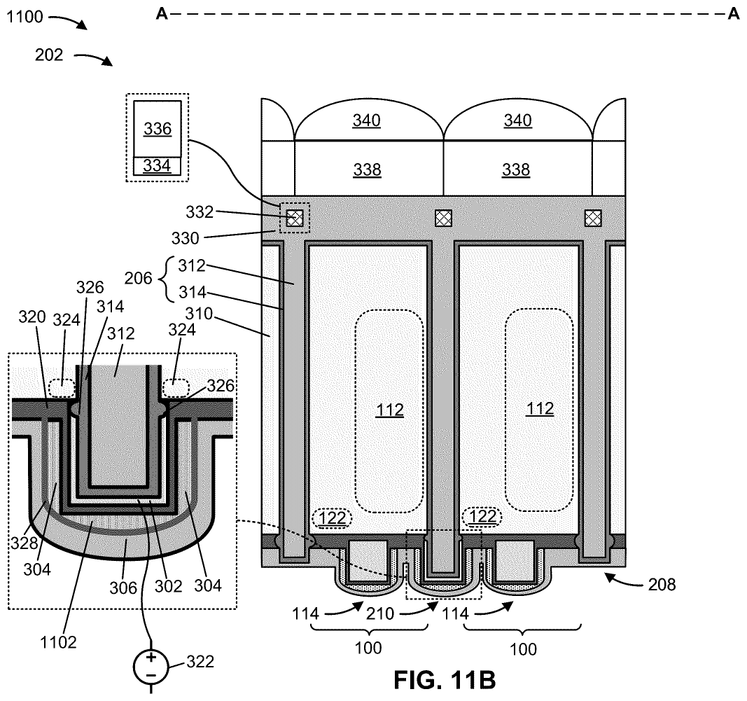

FIGS. 11A and 11B are diagrams of an example implementation 1100 of the pixel sensor array 202 described herein. FIG. 11A illustrates a perspective view of the example implementation 1100 of the pixel sensor array 202. FIG. 11B illustrates a cross-section view of the example implementation 1100 of the pixel sensor array 202. The cross-section view in FIG. 11B is along the cross-section A-A of the pixel sensor array 202 in FIGS. 2A and 2B.

As shown in FIGS. 11A and 11B, the pixel sensor array 202 in the example implementation 1100 includes a similar combination and arrangement of layers and structures as the example implementation 1000 of the pixel sensor array 202. However, in the example implementation 1100 of the pixel sensor array 202, additional spacer material is included over (or under) the polysilicon wells 302 in the cross-road portions 210 such that hard mask layers 1102 are included over (or under) the polysilicon wells 302 in the cross-road portions 210. The hard mask layers 1102 may be included between the oxide layer 320 and the oxide layer 328.

The hard mask layers 1102 over (or under) the polysilicon wells 302 in the cross-road portions 210 may further increase the over etch window for etching the recesses in which the BDTI structure 206 are formed, thereby further reducing the likelihood of defect formation in the pixel sensor array 202 and/or reducing process complexity for forming the pixel sensor array 202, among other examples. In some implementations, a combined thickness of a hard mask layer 1102 and the CESL 306 may be included in a range of approximately 700 angstroms to approximately 1000 angstroms. If the combined thickness is less than approximately 700 angstroms, the etch window for forming the recesses for the BDTI structure 206 may be reduced and/or etch damage may result to the semiconductor layer 310, whereas etch damage may be minimized if the combined thickness is at least approximately 700 angstroms. The combined thickness being greater than approximately 1000 angstroms, may result in under-etching when forming contacts to the transfer gates 114 and/or to the floating diffusion nodes 122, whereas the likelihood of under-etching may be reduced if the combined thickness is approximately 1000 angstroms or less. However, other values for the combined thickness, and ranges other than approximately 700 angstroms to approximately 1000 angstroms are within the scope of the present disclosure.

In this way, the pixel sensor array 202 includes a plurality of pixel sensors 100 and a BDTI structure 206 surrounding the plurality of pixel sensors 100. The BDTI structure 206 fully extends through the semiconductor layer 310 of the pixel sensor array 202 between a front side of the semiconductor layer 310 and a backside of the semiconductor layer 310. A portion of the BDTI structure 206 extends into and/or is surrounded by a polysilicon well 302 under the semiconductor layer 310. In some implementations, the portion of the BDTI structure 206 may be a non-cross-road portion 208 of the BDTI structure 206 between two pixel sensors 100 of the plurality of pixel sensors 100, and a cross-road portion 210 of the BDTI structure 206, at a corner of at least three pixel sensors 100 of the plurality of pixel sensors 100, may extend into another polysilicon well 302 under the semiconductor layer 310. A non-cross-road portion 208 of the BDTI structure 206, between two pixel sensors 100 of the plurality of pixel sensors 100, may extend into a portion of the CESL 306. A hard mask layer 1102 is included under a bottom surface of the polysilicon well 302.

In this way, the pixel sensor array 202 includes a plurality of pixel sensors 100 and a BDTI structure 206 surrounding the plurality of pixel sensors 100. The BDTI structure 206 fully extends through the semiconductor layer 310 of the pixel sensor array 202 between a front side of the semiconductor layer 310 and a backside of the semiconductor layer 310. The BDTI structure 206 extends into and/or is surrounded by a polysilicon well 302 under the semiconductor layer 310 at a cross-road portion 210 of the BDTI structure 206 and not at a non-cross-road portion 208. A non-cross-road portion 208 of the BDTI structure 206, between two pixel sensors 100 of the plurality of pixel sensors 100, may extend into a portion of the CESL 306.

As indicated above, FIGS. 11A and 11B are provided as an example. Other examples may differ from what is described with regard to FIGS. 11A and 11B.

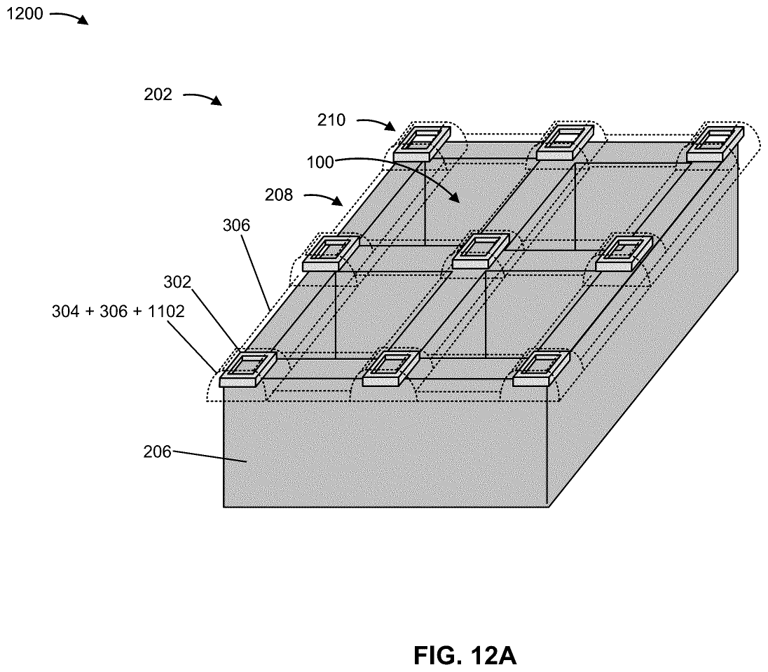

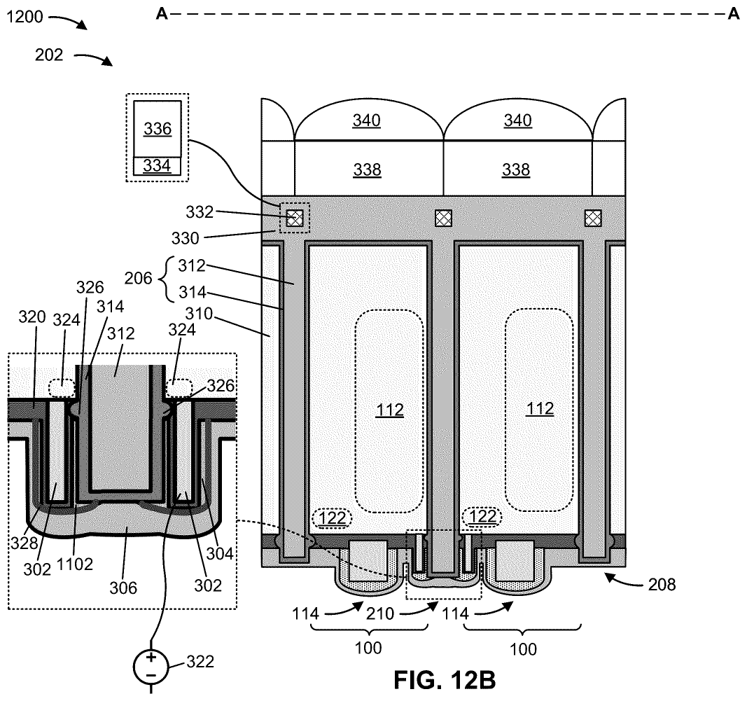

FIGS. 12A and 12B are diagrams of an example implementation 1200 of the pixel sensor array 202 described herein. FIG. 12A illustrates a perspective view of the example implementation 1200 of the pixel sensor array 202. FIG. 12B illustrates a cross-section view of the example implementation 1200 of the pixel sensor array 202. The cross-section view in FIG. 12B is along the cross-section A-A of the pixel sensor array 202 in FIGS. 2A and 2B.

As shown in FIGS. 12A and 12B, the pixel sensor array 202 in the example implementation 1200 includes a similar combination and arrangement of layers and structures as the example implementation 1100 of the pixel sensor array 202. However, in the example implementation 1200 of the pixel sensor array 202, ring-shaped polysilicon wells 302 may be included in the cross-road portions 210 of the BDTI structure 206. The BDTI structure 206 may extend through an aperture or opening in the ring-shaped polysilicon wells 302. The ring-shaped polysilicon wells 302 may be encapsulated by oxide layer 320. The dielectric sidewall spacers 304 and oxide layer 320 may be included between the BDTI structure 206 and the ring-shaped polysilicon wells 302.

The hard mask layers 1102 over (or under) the ring-shaped polysilicon wells 302 in the cross-road portions 210 may further increase the over etch window for etching the recesses in which the BDTI structure 206 are formed, thereby further reducing the likelihood of defect formation in the pixel sensor array 202 and/or reducing process complexity for forming the pixel sensor array 202, among other examples.

As indicated above, FIGS. 12A and 12B are provided as an example. Other examples may differ from what is described with regard to FIGS. 12A and 12B.

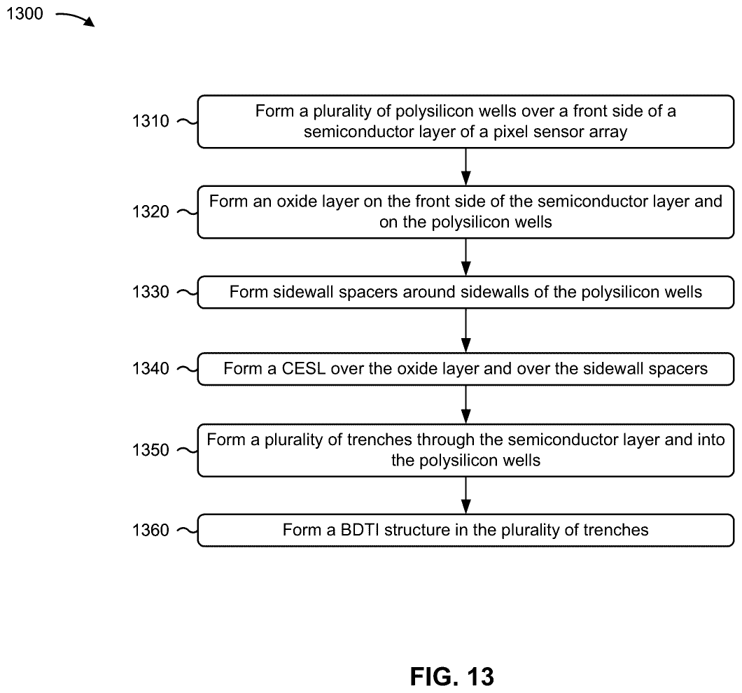

FIG. 13 is a flowchart of an example process 1300 associated with forming a pixel sensor array described herein. In some implementations, one or more process blocks of FIG. 13 are performed using one or more semiconductor processing tools.

As shown in FIG. 13, process 1300 may include forming a plurality of polysilicon wells over a front side of a semiconductor layer of a pixel sensor array (block 1310). For example, one or more semiconductor processing tools may be used to form a plurality of polysilicon wells 302 over a front side of a semiconductor layer 310 of a pixel sensor array 202, as described herein.

As further shown in FIG. 13, process 1300 may include forming an oxide layer on the front side of the semiconductor layer and on the polysilicon wells (block 1320). For example, one or more semiconductor processing tools may be used to form an oxide layer 320 on the front side of the semiconductor layer 310 and on the polysilicon wells 302, as described herein.

As further shown in FIG. 13, process 1300 may include forming sidewall spacers around sidewalls of the polysilicon wells (block 1330). For example, one or more semiconductor processing tools may be used to form sidewall spacers (e.g., dielectric sidewall spacers 304) around sidewalls of the polysilicon wells 302, as described herein.

As further shown in FIG. 13, process 1300 may include forming a CESL over the oxide layer and over the sidewall spacers (block 1340). For example, one or more semiconductor processing tools may be used to form a CESL 306 over the oxide layer 320 and over the sidewall spacers, as described herein.

As further shown in FIG. 13, process 1300 may include forming a plurality of recesses through the semiconductor layer and into the polysilicon wells (block 1350). For example, one or more semiconductor processing tools may be used to form a plurality of recesses (e.g., recesses 502, recesses 702, recesses 902) through the semiconductor layer 310 and into the polysilicon wells 302, as described herein. In some implementations, the plurality of recesses are formed from a backside of the semiconductor layer 310 to the front side of the semiconductor layer 310. Alternatively, the polysilicon wells 302 include ring-shaped polysilicon wells 302, and the recesses are formed through an aperture of the ring-shaped polysilicon wells 302 (e.g., within an inner perimeter of the ring-shaped polysilicon wells 302).

As further shown in FIG. 13, process 1300 may include forming a BDTI structure in the plurality of recesses (block 1360). For example, one or more semiconductor processing tools may be used to form a BDTI structure 206 in the plurality of recesses, as described herein.

Process 1300 may include additional implementations, such as any single implementation or any combination of implementations described below and/or in connection with one or more other processes described elsewhere herein.

In a first implementation, forming the oxide layer 320 includes forming the oxide layer 320 such that a thickness of the oxide layer 320 on the front side of the semiconductor layer is greater than a thickness of the oxide layer 320 on the polysilicon wells 302.

In a second implementation, alone or in combination with the first implementation, process 1300 includes forming hard mask layers 1102 over top surfaces of the polysilicon wells 302, where forming the CESL 306 includes forming the CESL 306 over the hard mask layers 1102.

In a third implementation, alone or in combination with one or more of the first and second implementations, forming the BDTI structure 206 includes forming one or more dielectric liners (e.g., a dielectric liner 314, a dielectric liner 802) on sidewalls and on a bottom surface of a recess of the plurality of recesses, and filling the recess with an oxide-containing material (e.g., a dielectric material 312) over the one or more dielectric liners.

In a fourth implementation, alone or in combination with one or more of the first through third implementations, forming the BDTI structure 206 includes forming a dielectric liner (e.g., a dielectric liner 314, a dielectric liner 802) on sidewalls and on a bottom surface of a recess of the plurality of recesses, removing a portion of the dielectric liner from the bottom surface of the recess to expose a polysilicon well 302 of the plurality of polysilicon wells 302 through the bottom surface of the recess, and filling the recess with a polysilicon material 602, wherein the polysilicon material is formed directly on the polysilicon well 302 at the bottom surface of the recess.

In a fifth implementation, alone or in combination with one or more of the first through fourth implementations, forming the dielectric liner further includes forming the dielectric liner on the backside of the semiconductor layer 310 such that a first thickness of the dielectric liner on the backside of the semiconductor layer 310 is greater than a second thickness of the dielectric liner on the bottom surface of the recess, and removing the portion of the dielectric liner from the bottom surface of the recess results in removal of the dielectric liner from the backside of the semiconductor layer 310.

In a sixth implementation, alone or in combination with one or more of the first through fifth implementations, forming the BDTI structure 206 includes forming a plurality of dielectric liners (e.g., a dielectric liner 314, a dielectric liner 802) on sidewalls and on a bottom surface of a recess of the plurality of recesses, removing portions of the plurality of dielectric liners from the bottom surface of the recess to expose a polysilicon well 302 of the plurality of polysilicon wells through the bottom surface of the recess, and filling the recess with a polysilicon material 602, where the polysilicon material 602 is formed directly on the polysilicon well 302 at the bottom surface of the recess.

Although FIG. 13 shows example blocks of process 1300, in some implementations, process 1300 includes additional blocks, fewer blocks, different blocks, or differently arranged blocks than those depicted in FIG. 13. Additionally, or alternatively, two or more of the blocks of process 1300 may be performed in parallel.

In this way, a polysilicon well is formed at a cross-road portion between a plurality of pixel sensors in a pixel sensor array. Moreover, the underlying oxide layer between the polysilicon well and a semiconductor layer of the pixel sensor array may be thinner than other areas of the oxide layer. The polysilicon well and the thinner oxide layer may reduce the likelihood of and/or the magnitude of lateral etching that occurs during etching of the semiconductor layer to form recesses in which a BDTI structure of the pixel sensor array is formed. Moreover, the bottom of the BDTI structure extending into the polysilicon well enables a voltage bias to be applied to the BDTI structure through the polysilicon well to passivate damage that might have occurred to the semiconductor layer around the bottom of the BDTI structure.

As described in greater detail above, some implementations described herein provide a pixel sensor array. The pixel sensor array includes a plurality of pixel sensors. The pixel sensor array includes a BDTI structure surrounding the plurality of pixel sensors, where the BDTI structure fully extends through a semiconductor layer of the pixel sensor array between a front side of the semiconductor layer and a backside of the semiconductor layer, and where a portion of the BDTI structure extends into and/or is surrounded by a polysilicon well under the semiconductor layer.

As described in greater detail above, some implementations described herein provide a method. The method includes forming a plurality of polysilicon wells over a front side of a semiconductor layer of a pixel sensor array. The method includes forming an oxide layer on the front side of the semiconductor layer and on the polysilicon wells. The method includes forming sidewall spacers around sidewalls of the polysilicon wells. The method includes forming a CESL over the oxide layer and over the sidewall spacers. The method includes forming a plurality of trenches through the semiconductor layer and into the polysilicon wells, where the plurality of trenches are formed from a backside of the semiconductor layer to the front side of the semiconductor layer. The method includes forming a BDTI structure in the plurality of trenches.

As described in greater detail above, some implementations described herein provide a pixel sensor array. The pixel sensor array includes a plurality of pixel sensors. The pixel sensor array includes a BDTI structure that fully extends through a semiconductor layer of the pixel sensor array between a front side of the semiconductor layer and a backside of the semiconductor layer, where a bottom portion of the BDTI structure extends into and/or is surrounded by one or more dielectric layers under the semiconductor layer, and where a ring-shaped polysilicon well is included around the bottom portion of the BDTI structure in the one or more dielectric layers.

As used herein, “satisfying a threshold” may, depending on the context, refer to a value being greater than the threshold, greater than or equal to the threshold, less than the threshold, less than or equal to the threshold, equal to the threshold, not equal to the threshold, or the like.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A pixel sensor array, comprising:
a plurality of pixel sensors; and
a backside deep trench isolation (BDTI) structure at least laterally surrounding the plurality of pixel sensors,
wherein the BDTI structure is included fully through a semiconductor layer of the pixel sensor array between a front side of the semiconductor layer and a backside of the semiconductor layer, and
wherein a portion of the BDTI structure is surrounded by a polysilicon well under the semiconductor layer.

2. The pixel sensor array of claim 1, wherein the portion of the BDTI structure is a non-cross-road portion of the BDTI structure between two pixel sensors of the plurality of pixel sensors; and
wherein a cross-road portion of the BDTI structure, at a corner of at least three pixel sensors of the plurality of pixel sensors, is surrounded by another polysilicon well under the semiconductor layer.

3. The pixel sensor array of claim 2, wherein a first distance between a bottom of the polysilicon well and a bottom of the non-cross-road portion of the BDTI structure is greater than a second distance between a bottom of the other polysilicon well and a bottom of the cross-road portion of the BDTI structure.

4. The pixel sensor array of claim 1, wherein the polysilicon well is configured to be electrically biased to increase hole density around the portion of the BDTI structure.

5. The pixel sensor array of claim 1, wherein the portion of the BDTI structure is a cross-road portion of the BDTI structure at a corner of at least three of the pixel sensors of the plurality of pixel sensors;
wherein a dielectric sidewall spacer is included around sidewalls of the polysilicon well;
wherein a contact etch stop layer (CESL) is included around the dielectric sidewall spacer and under a bottom surface of the polysilicon well; and
wherein a non-cross-road portion of the BDTI structure, between two pixel sensors of the plurality of pixel sensors, is surrounded by a portion of the CESL.

6. The pixel sensor array of claim 1, wherein the portion of the BDTI structure is a cross-road portion of the BDTI structure at a corner of at least three of the pixel sensors of the plurality of pixel sensors;
wherein a dielectric sidewall spacer is included around sidewalls of the polysilicon well;
wherein a hard mask layer is included under a bottom surface of the polysilicon well;
wherein a contact etch stop layer (CESL) is included under and around the dielectric sidewall spacer and the hard mask layer; and
wherein a non-cross-road portion of the BDTI structure, between two pixel sensors of the plurality of pixel sensors, is surrounded by a portion of the CESL.

7. The pixel sensor array of claim 1, wherein the BDTI structure comprises:
polysilicon trench structures arranged in an interconnected grid around the plurality of pixel sensors; and
one or more dielectric liners between the polysilicon trench structures and the semiconductor layer,
wherein the portion of the BDTI structure is electrically coupled with the polysilicon well.

8. The pixel sensor array of claim 7, wherein the portion of the BDTI structure is configured to be electrically biased through the polysilicon well to increase hole density around the portion of the BDTI structure.

9. The pixel sensor array of claim 7, wherein the one or more dielectric liners comprise at least one of:
an oxide-containing dielectric liner, or
a high dielectric constant (high-k) dielectric liner.

10. A method, comprising:
forming a plurality of polysilicon wells over a first side of a semiconductor layer of a pixel sensor array;
forming an oxide layer on the first side of the semiconductor layer and on the polysilicon wells;
forming sidewall spacers around sidewalls of the polysilicon wells;
forming a contact etch stop layer (CESL) over the oxide layer and over the sidewall spacers;
forming a plurality of trenches through the semiconductor layer and into the polysilicon wells,
wherein the plurality of trenches are formed from a second side of the semiconductor layer to the first side of the semiconductor layer; and
forming a backside deep trench isolation (BDTI) structure in the plurality of trenches.

11. The method of claim 10, wherein forming the oxide layer comprises:
forming the oxide layer such that a thickness of the oxide layer on the first side of the semiconductor layer is greater than a thickness of the oxide layer on the polysilicon wells.

12. The method of claim 10, further comprising:
forming hard mask layers over top surfaces of the polysilicon wells,
wherein forming the CESL comprises:
forming the CESL over the hard mask layers.

13. The method of claim 10, wherein forming the BDTI structure comprises:
forming one or more dielectric liners on sidewalls and on a bottom surface of a trench of the plurality of trenches; and
filling the trench with an oxide-containing material over the one or more dielectric liners.

14. The method of claim 10, wherein forming the BDTI structure comprises:
forming a dielectric liner on sidewalls and on a bottom surface of a trench of the plurality of trenches;
removing a portion of the dielectric liner from the bottom surface of the trench to expose a polysilicon well of the plurality of polysilicon wells through the bottom surface of the trench; and
filling the trench with a polysilicon material,
wherein the polysilicon material is formed directly on the polysilicon well at the bottom surface of the trench.

15. The method of claim 14, wherein forming the dielectric liner further comprises:
forming the dielectric liner on the second of the semiconductor layer such that a first thickness of the dielectric liner on the second of the semiconductor layer is greater than a second thickness of the dielectric liner on the bottom surface of the trench; and
wherein removing the portion of the dielectric liner from the bottom surface of the trench results in removal of the dielectric liner from the second of the semiconductor layer.

16. The method of claim 10, wherein forming the BDTI structure comprises:
forming a plurality of dielectric liners on sidewalls and on a bottom surface of a trench of the plurality of trenches;
removing portions of the plurality of dielectric liners from the bottom surface of the trench to expose a polysilicon well of the plurality of polysilicon wells through the bottom surface of the trench; and
filling the trench with a polysilicon material,
wherein the polysilicon material is formed directly on the polysilicon well at the bottom surface of the trench.

17. A pixel sensor array, comprising:
a plurality of pixel sensors; and
a backside deep trench isolation (BDTI) structure that is included fully through a semiconductor layer of the pixel sensor array between a front side of the semiconductor layer and a backside of the semiconductor layer,
wherein a bottom portion of the BDTI structure is surrounded by one or more dielectric layers under the semiconductor layer, and
wherein a ring-shaped polysilicon well is included around the bottom portion of the BDTI structure in the one or more dielectric layers.

18. The pixel sensor array of claim 17, wherein the one or more dielectric layers comprise an oxide layer between the ring-shaped polysilicon well and the BDTI structure.

19. The pixel sensor array of claim 17, wherein the one or more dielectric layers comprise a silicon nitride (SiₓN_{y}) spacer layer between the ring-shaped polysilicon well and the BDTI structure.

20. The pixel sensor array of claim 17, wherein the one or more dielectric layers comprise a contact etch stop layer (CESL) around and under the ring-shaped polysilicon well; and
wherein the CESL is included between the ring-shaped polysilicon well and another ring-shaped polysilicon well around another bottom portion of the BDTI structure.
